(19) United States
(12) Patent Application Publication
(10) Pub. No.: US 2026/0304976 A1
(43) Pub. Date: Oct. 1, 2026

(54) IMAGE SENSOR INCLUDING FLOATING DIFFUSION REGION

(71) Applicant: Samsung Electronics Co., Ltd., Suwon-si (KR)

(72) Inventors: Myungjo Jung, Suwon-si (KR); Yongjun Kim, Suwon-si (KR); Sunhee Yun, Suwon-si (KR); Sol Yoon, Suwon-si (KR); Segyo Han, Suwon-si (KR)

(73) Assignee: Samsung Electronics Co., Ltd., Suwon-si (KR)

(21) Appl. No.: 19/467,338

(22) Filed: Feb. 2, 2026

(30) Foreign Application Priority Data
Mar. 25, 2025 (KR) 10-2025-0013403

(51) Int. Cl. H10F 39/00; H10F 39/18

(52) U.S. Cl. CPC H10F 39/80373; H10F 39/014; H10F 39/182

(57) ABSTRACT

An image sensor includes a unit pixel, a pad pattern and a contact plug. The unit pixel includes a photodiode, a pair of vertical transfer gates, and a floating diffusion region. The photodiode is disposed in a substrate and doped with n-type impurities. The pair of vertical transfer gates are disposed on the photodiode, and each of the pair of vertical transfer gates extends through a portion of the substrate. The floating diffusion region is disposed at an upper portion of the substrate between the pair of vertical transfer gates, and includes first impurities. The pad pattern is disposed on the floating diffusion region, and includes polysilicon doped with the first impurities. The contact plug is disposed on an upper surface of the pad pattern.

### CROSS-REFERENCE TO RELATED APPLICATIONS

This present application claims priority to and the benefit under 35 USC § 119(a)-(d) of Korean Patent Application No. 10-2025-0013403, filed on Feb. 3, 2025, in the Korean Intellectual Property Office, the entire disclosure of which is incorporated herein by reference.

### FIELD

Example embodiments relate to an image sensor and more particularly to an image sensor including a floating diffusion region.

### BACKGROUND

A CMOS image sensor operates by transferring charges generated in a photodiode to a floating diffusion region through a vertical transfer gate and converting the charges into a voltage signal to acquire an image. Charge-to-voltage conversion efficiency in the floating diffusion region, that is, a conversion gain is an important factor that determines the sensitivity of the sensor.

### SUMMARY

According to example embodiments, there is provided an image sensor. The image sensor may include a unit pixel, a pad pattern and a contact plug. The unit pixel may include a photodiode, a pair of vertical transfer gates, and a floating diffusion region. The photodiode may be disposed in a substrate and doped with n-type impurities. The pair of vertical transfer gates may be disposed on the photodiode, and each of the pair of vertical transfer gates may extend through a portion of the substrate. The floating diffusion region may be disposed at an upper portion of the substrate between the pair of vertical transfer gates, and may include first impurities. The pad pattern may be disposed on the floating diffusion region, and may include polysilicon doped with the first impurities. The contact plug may be disposed on an upper surface of the pad pattern.

According to example embodiments, there is provided an image sensor. The image sensor may include a substrate, a pad structure, and a common floating diffusion region. The substrate may have a pixel group including unit pixels arranged in a matrix having two rows and two columns. The pad structure may be disposed on the substrate, and may include a first central portion and first, second, third and fourth extension portions. The first central portion may be disposed at a center of the pixel group of the substrate in a plan view, and the first, second, third and fourth extension portions may extend from the first central portion toward centers of the unit pixels, respectively, of the substrate in a plan view. The pad structure may include polysilicon doped with first impurities. The common floating diffusion region may be disposed at an upper portion of the substrate overlapping the pad structure in a vertical direction substantially perpendicular to an upper surface of the substrate, and may include the first impurities. Each of the unit pixels may include a photodiode and a pair of vertical transfer gates. The photodiode may be disposed in the substrate, and may be doped with n-type impurities. The pair of vertical transfer gates may be disposed on the photodiode, and each of the pair of vertical transfer gates may extend through a portion of the substrate.

According to example embodiments, there is provided an image sensor. The image sensor may include a substrate, a pad structure, and a common floating diffusion region. The substrate may have a pixel group including unit pixels arranged in a matrix having two rows and two columns. The pad structure may be disposed on the substrate, and may include a first central portion and first, second, third and fourth extension portions. The first central portion may be disposed at a center of the pixel group of the substrate in a plan view, and the first, second, third and fourth extension portions may extend from the first central portion toward centers of the unit pixels, respectively, of the substrate in a plan view. The pad structure may include polysilicon doped with first impurities. The common floating diffusion region may be disposed at an upper portion of the substrate overlapping the pad structure in a vertical direction substantially perpendicular to an upper surface of the substrate. The common floating diffusion region may include the first impurities. Each of the unit pixels may include a photodiode and a pair of vertical transfer gates. The photodiode may be disposed in the substrate, and may be doped with n-type impurities. The pair of vertical transfer gates may be disposed on the photodiode, and each of the pair of vertical transfer gates may extend through a portion of the substrate.

### BRIEF DESCRIPTION OF THE DRAWINGS

FIG. 1 is a plan view illustrating a layout of a pixel group included in an image sensor in accordance with example embodiments.

FIG. 2 is an enlarged plan view of a first unit pixel included in the pixel group in FIG. 1.

FIG. 3 is a vertical cross-sectional view taken along line A-A′ of FIG. 1.

FIG. 4 is a vertical cross-sectional view taken along line B-B′ of FIG. 1.

FIGS. 5 to 24 are plan views and cross-sectional views illustrating a method of manufacturing an image sensor in accordance with example embodiments.

FIGS. 25 and 26 are a plan view and a cross-sectional view, respectively, illustrating an image sensor in accordance with example embodiments.

FIG. 27 is a plan view illustrating an image sensor in accordance with example embodiments.

FIG. 28 is a plan view illustrating an image sensor in accordance with example embodiments.

FIG. 29 is a plan view illustrating an image sensor in accordance with example embodiments.

FIG. 30 is a cross-sectional view illustrating an image sensor in accordance with example embodiments.

FIG. 31 is a cross-sectional view illustrating an image sensor in accordance with example embodiments.

FIG. 32 is a cross-sectional view illustrating an image sensor in accordance with example embodiments.

FIGS. 33 to 38 are cross-sectional views illustrating a method of manufacturing an image sensor in accordance with some example embodiments.

FIG. 39 is a cross-sectional view illustrating an image sensor in accordance with example embodiments.

FIGS. 40 to 43 are cross-sectional views illustrating a method of manufacturing an image sensor in accordance with example embodiments.

### DETAILED DESCRIPTION

Image sensors in accordance with example embodiments will be more clearly understood from the following detailed description taken in conjunction with the accompanying drawings.

It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of disclosed concepts.

Two directions, among horizontal directions that are substantially parallel to first and second surfaces of a substrate, which are substantially perpendicular to one another may be referred to as first and second directions D1 and D2, respectively, and a vertical direction substantially perpendicular to the first and second surfaces of the substrate may be referred to as a third direction D3. Two directions among the horizontal directions that form angles of about 45 degrees with respect to the first and second directions D1 and D2 may be referred to as fourth and fifth directions D4 an D5, respectively. In example embodiments, the first and second directions D1 and D2 may be substantially perpendicular to one another, and the fourth and fifth directions D4 and D5 may be substantially perpendicular to one another.

In the image sensor in accordance with example embodiments, the floating diffusion region may have a reduced volume, and the charge-to-voltage conversion efficiency may be improved. Additionally, the contact plug may not contact the floating diffusion region at an upper portion of the substrate, but may contact the pad structure. Thus, during an etching process for forming the contact plug, the substrate may not be damaged so as to reduce leakage current.

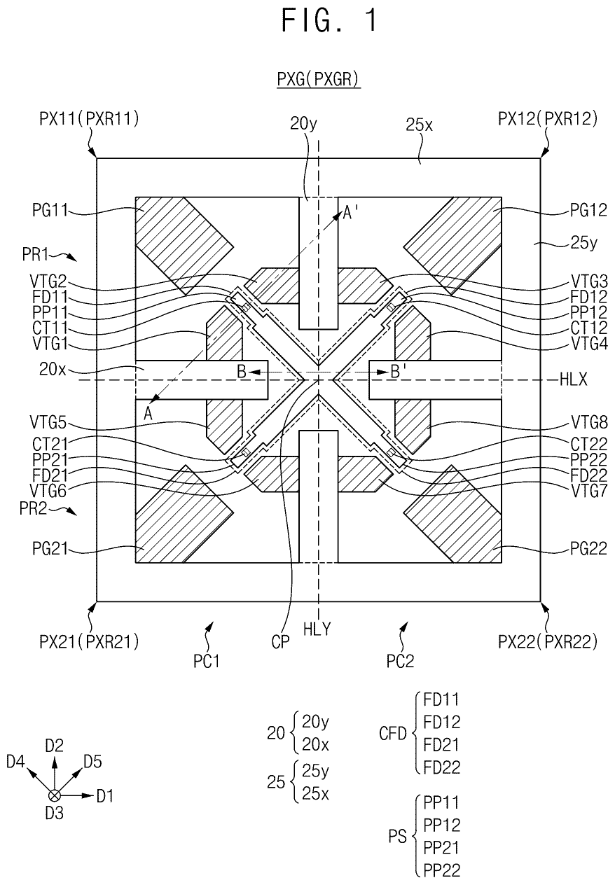

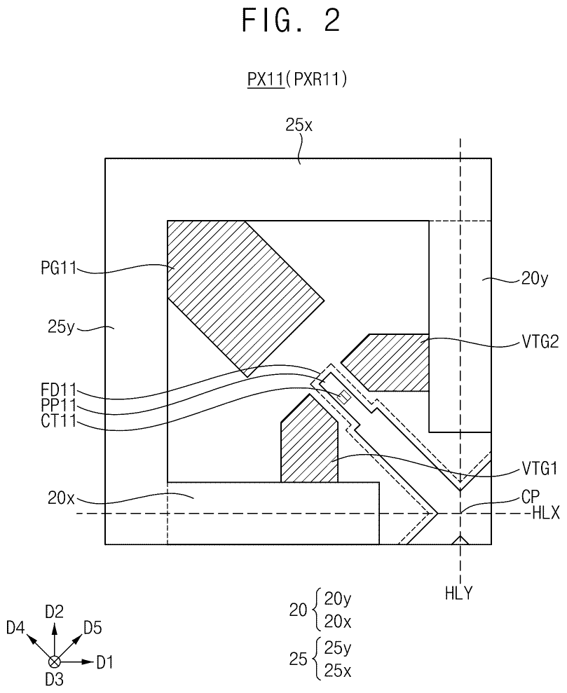

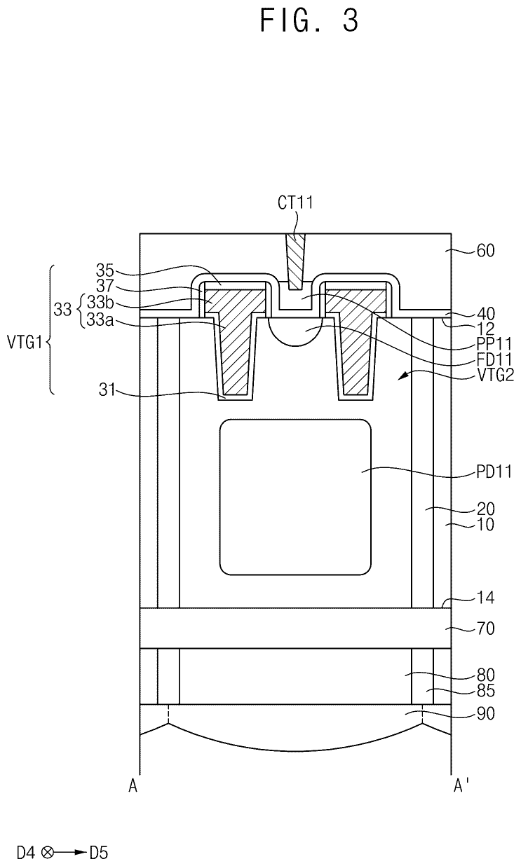

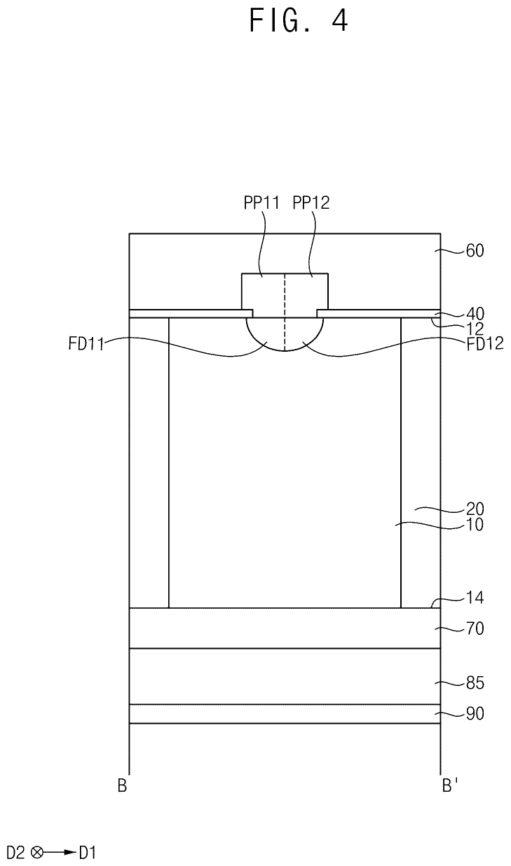

FIG. 1 is a plan view illustrating a layout of a pixel group included in an image sensor in accordance with example embodiments. FIG. 2 is an enlarged plan view of a first unit pixel included in the pixel group in FIG. 1. FIG. 3 is a vertical cross-sectional view taken along line A-A′ of FIG. 1. FIG. 4 is a vertical cross-sectional view taken along line B-B′ of FIG. 1.

Referring to FIGS. 1 to 4, the image sensor may include a division structure 30, a pixel group PXG, a pad structure PS, and first, second, third and fourth contact plugs CT11, CT12, CT21 and CT22. In PXij, i denotes an index of a pixel row, and j denotes an index of a pixel column.

The image sensor may further include an etch stop layer 40, an insulating interlayer 60, a planarization layer 70, color filters 80, a grid 85 and an optical structure 90.

In some embodiments, a transparent electrode layer may be further disposed on the optical structure 90.

The substrate 10 may include first and second surfaces 12 and 14 opposite to one another in the third direction D3.

In example embodiments, the substrate 10 may include a semiconductor material, e.g., silicon, germanium, silicon-germanium, etc., or a III-V group compound semiconductor, e.g., GaP, GaAs, GaSb, etc. In example embodiments, a p-type well may be formed in a portion or an entire portion of the substrate 10.

The division structure 30 may extend through the substrate 10 in the third direction D3. In example embodiments, the division structure 30 may have a shape of, e.g., a lattice in a plan view.

The division structure 30 may be disposed in the substrate 10 and may separate unit pixels from one another. Thus, unit pixel regions in which unit pixels are respectively formed may be defined in the substrate 10. However, in some cases, the unit pixel regions may also include spaces over and under the substrate 10.

The pixel group PXG may include the unit pixels, e.g., first, second, third and fourth pixels PX11, PX12, PX21 and PX22. The first, second, third and fourth pixels PX11, PX12, PX21 and PX22 may be arranged in a matrix having two pixel rows PR1 and PR2 and two pixel columns PC1 and PC2.

In example embodiments, a plurality of pixel groups PXG may be arranged in each of the first and second directions D1 and D2 to form a pixel array. FIG. 1 shows a single pixel group PXG.

In the image sensor, the unit pixel regions in which the first to fourth pixels PX11, PX12, PX21 and PX22 are respectively disposed may be referred to as first to fourth pixel regions PXR11, PXR12, PXR21 and PXR22, respectively. Additionally, a region in which the pixel group is formed, for example, first to fourth pixel regions PXR11, PXR12, PXR21 and PXR22 in which the first to fourth pixels PX11, PX12, PX21 and PX22 are respectively formed may be collectively referred to as a pixel group region PXGR.

The division structure 30 may include an inter-group division structure 25, which may separate neighboring ones of the pixel groups PXG from one another, and an inter-pixel division structure 20, which may separate neighboring ones of unit pixels, e.g., the first to fourth pixels PX11, PX12, PX21 and PX22 included in the pixel group PXG from one another.

The inter-group division structure 25 may include first inter-group division patterns 25x and second inter-group division patterns 25y. Each of the first inter-group division patterns 25x may extend in the first direction D1 between neighboring ones of the pixel groups PXG in the second direction D2, and the first inter-group division patterns 25x may be spaced apart from one another in the second direction D2. Each of the second inter-group division patterns 25y may extend in the second direction D2 between neighboring ones of the pixel groups PXG in the first direction D1, and the second inter-group division patterns 25y may be spaced apart from one another in the first direction D1. The first inter-group division patterns 25x and the second inter-group division patterns 25y may cross one another at an intersection thereof.

The inter-group division structure 25 may prevent crosstalk between neighboring ones of the pixel groups PXG.

The inter-pixel division structure 20 may include first inter-pixel division patterns 20x and second inter-pixel division patterns 20y. Each of the first inter-pixel division patterns 20x may extend in the first direction D1 between the first and third pixels PX11 and PX21 and between the second and fourth pixels PX12 and PX22, and may be connected to the second inter-group division patterns 25y. The first inter-pixel division patterns 20x may be spaced apart from one another in the first direction D1 at a center CP of the pixel group PXG. Each of the second inter-pixel division patterns 20y may extend in the second direction D2 between the first and second pixels PX11 and PX12 and between the third and fourth pixels PX21 and PX22, and may be connected to the first inter-group division patterns 25x.

The inter-pixel division structure 20 may prevent crosstalk between neighboring ones of the unit pixels, e.g., the first to fourth pixels PX11, PX12, PX21 and PX22 in each of the pixel groups PXG.

In example embodiments, the division structure 30 may include an insulating material, e.g., an oxide, a nitride, etc., or a semiconductor material, e.g., polysilicon. Alternatively, the division structure 30 may include a conductive material, e.g., a metal, a metal nitride, etc.

Each of the unit pixels may include a photoelectric conversion element, e.g., a photodiode, a pair of vertical transfer gates (TG), and a floating diffusion region (FD). The pair of vertical transfer gates may extend in the third direction D3 from the first surface 12 of the substrate 10 into an inside of the substrate 10, and may transfer optical charges collected by the photoelectric conversion element to the floating diffusion region. The photoelectric conversion element, the pair of vertical transfer gates and the floating diffusion region may collectively form a transfer transistor.

Each of the unit pixels may further include pixel gates. For example, the pixel gates may include, e.g., a source follower gate, a reset gate and a select gate. The pixel gate and a source/drain region at an upper portion of the substrate 10 may collectively form a pixel transistor, e.g., a source follower transistor, a reset transistor and a select transistor.

In example embodiments, the first pixel PX11 may have a transfer transistor including a first photodiode PD11, a first vertical transfer gate VTG1, a second vertical transfer gate VTG2, and a first floating diffusion region FD11. In example embodiments, the first pixel PX11 may also have a first rest transistor including a first pixel gate PG11 and a source/drain region adjacent thereto.

In example embodiments, the second pixel PX12 may have a transfer transistor including a second photodiode, a third vertical transfer gate VTG3, a fourth vertical transfer gate VTG4, and a second floating diffusion region FD12. In example embodiments, the second pixel PX12 may also have a second rest transistor including a second pixel gate PG12 and a source/drain region adjacent thereto.

In example embodiments, the third pixel PX21 may have a transfer transistor including a third photodiode, a fifth vertical transfer gate VTG5, a sixth vertical transfer gate VTG6, and a third floating diffusion region FD21. In example embodiments, the third pixel PX21 may also have a select transistor including a third pixel gate PG21 and a source/drain region adjacent thereto.

In example embodiments, the fourth pixel PX22 may have a transfer transistor including a fourth photodiode, a seventh vertical transfer gate VTG7, an eighth vertical transfer gate VTG8, and a fourth floating diffusion region FD22. In example embodiments, the fourth pixel PX22 may also have a source follower transistor including a fourth pixel gate PG22 and a source/drain region adjacent thereto.

The first to fourth floating diffusion regions FD11, FD12, FD21 and FD22 may be connected to one another at the center CP of the pixel group PXG. The first to fourth floating diffusion regions FD11, FD12, FD21 and FD22 may collectively form a common floating diffusion region CFD. The common floating diffusion region CFD may be shared by the first to fourth pixels PX11, PX12, PX21 and PX22 of the pixel group PXG.

The first floating diffusion region FD11 may extend from the center CP of the pixel group PXG toward a center of the first pixel PX11. The second floating diffusion region FD12 may extend from the center CP of the pixel group PXG toward a center of the second pixel PX12. The third floating diffusion region FD21 may extend from the center CP of the pixel group PXG toward a center of the third pixel PX21. The fourth floating diffusion region FD22 may extend from the center CP of the pixel group PXG toward a center of the fourth pixel PX22. Thus, the common floating diffusion region CFD including the first to fourth floating diffusion regions FD11, FD12, FD21 and FD22 may have a shape of an “X” in a plan view.

Each of the first to fourth floating diffusion regions FD11, FD12, FD21 and FD22 may be disposed at an upper portion of the substrate 10 adjacent the first surface 12 thereof. Each of the first to fourth floating diffusion regions FD11, FD12, FD21 and FD22 may further include a first impurities, e.g., n-type impurities.

The etch stop layer 40 may cover the first to eighth vertical transfer gates VTG1, VTG2, VTG3, VTG4, VTG5, VTG6, VTG7 and VTG8, the first to fourth pixel gates PG11, PG12, PG21 and PG22, and the first surface 12 of the substrate 10. The etch stop layer 40 may include an oxide, e.g., silicon oxide.

The pad structure PS may include first, second, third and fourth pad patterns PP11, PP12, PP21 and PP22. The first to fourth pad patterns PP11, PP12, PP21 and PP22 may extend through the etch stop layer 40 to contact upper surfaces of the first to fourth diffusion regions FD11, FD12, FD21 and FD22, respectively.

The pad structure PS including the first to fourth pad patterns PP11, PP12, PP21 and PP22 may have a shape of an “X” in a plan view, corresponding to the shape of the common floating diffusion region CFD. That is, the first pad pattern PP11 may extend from the center CP of the pixel group PXG toward the center of the first pixel PX11. The second pad pattern PP12 may extend from the center CP of the pixel group PXG toward the center of the second pixel PX12. The third pad pattern PP21 may extend from the center CP of the pixel group PXG toward the center of the third pixel PX21. The fourth pad pattern PP22 may extend from the center CP of the pixel group PXG toward the center of the fourth pixel PX22.

Each of the first to fourth pad patterns PP11, PP12, PP21 and PP22 may include polysilicon doped with the first impurities. The first impurities may be doped into the first to fourth pad patterns PP11, PP12, PP21 and PP22 from the first to fourth floating diffusion regions FD11, FD12, FD21 and FD22, respectively.

The first to fourth contact plugs CT11, CT12, CT21 and CT22 may extend through the insulating interlayer 60 to contact upper surfaces of the first to fourth pad patterns PP11, PP12, PP21 and PP22, respectively. Thus, the first to fourth contact plugs CT11, CT12, CT21 and CT22 may be electrically connected to the first to fourth floating diffusion regions FD11, FD12, FD21 and FD22, respectively, through the first to fourth pad patterns PP11, PP12, PP21 and PP22, respectively.

In example embodiments, a lower surface of each of the first to fourth contact plugs CT11, CT12, CT21 and CT22 may be higher than the first surface 12 of the substrate 10.

In example embodiments, the first contact plug CT11 may contact an upper surface of a portion of the first pad pattern PP11 that is disposed between sidewalls of the first and second vertical transfer gates VTG1 and VTG2 opposite to one another in the fifth direction D5. In example embodiments, the second contact plug CT12 may contact an upper surface of a portion of the second pad pattern PP12 that is disposed between sidewalls of the third and fourth vertical transfer gates VTG3 and VTG4 opposite to one another in the fourth direction D4. In example embodiments, the third contact plug CT21 may contact an upper surface of a portion of the third pad pattern PP21 that is disposed between sidewalls of the fifth and sixth vertical transfer gates VTG5 and VTG6 opposite to one another in the fourth direction D5. In example embodiments, the fourth contact plug CT22 may contact an upper surface of a portion of the fourth pad pattern PP22 that is disposed between sidewalls of the seventh and eighth vertical transfer gates VTG7 and VTG8 opposite to one another in the fifth direction D5.

The first reset transistor including the first pixel gate PG11, the second reset transistor including the second pixel gate PG12, the select transistor including the third pixel gate PG21, and the source follower transistor including the fourth pixel gate PG22 may be shared by the first to fourth pixels PX11, PX12, PX21 and PX22 of the pixel group PXG.

The planarization layer 70 may be disposed on the second surface 14 of the substrate 10, and may have a single layer or a multi-layered structure having a plurality of layers, e.g., first to fifth layers stacked in the third direction D3. The first to fifth layers may include, e.g., aluminum oxide, hafnium oxide, silicon oxide, silicon nitride and hafnium oxide, respectively.

The color filters 80 may be disposed on the planarization layer 70, and may be spaced apart from one another by the grid 85 corresponding to the division structure 30. The grid 85 may have a shape of a lattice in a plan view, corresponding to the shape of the division structure 30.

The grid 85 may serve as a barrier that may prevent lights entering one pixel from entering an adjacent pixel, so that optical interference between neighboring pixels may be prevented. The grid 85 may include, e.g., a low refractive index material (LRIM).

The optical structure 90 may be disposed under the color filters 80 and the grid 85, and may collect light incident on the pixels. FIG. 3 shows that the optical structure 90 is a microlens, however, the disclosed concepts are not limited thereto, and the optical structure 90 may include, e.g., a nano-prism.

The pixel group PXG may be symmetric with respect to a first horizontal line HLX that passes through the center CP of the pixel group PXG and extends in the first direction D1. Additionally, the pixel group PXG may be symmetric with respect to a second horizontal line HLY that passes through the center CP of the pixel group PXG and perpendicular to the first horizontal line HLX. Hereinafter, only the first pixel PX11 is illustrated with reference to FIGS. 2 and 3, however, each of the second to fourth pixels PX12, PX21 and PX22 may have substantially the same structure as the first pixel PX11 according to the symmetry of the pixel group PXG.

The first pixel PX11 may include the first photodiode PD11, the first floating diffusion region FD11, the first and second vertical transfer gates VTG1 and VTG2, the first pad pattern PP11 and the first pixel gate PG11.

For example, the first photodiode PD11 may be a region doped with n-type impurities in the p-type well in the substrate 10.

In example embodiments, the first photodiode PD11 may be disposed in the first pixel region PXR11 among the unit pixel regions of the substrate 10 that may be defined by the division structure 30. FIG. 3 shows that a single first photodiode PD11 is disposed in the first pixel region PXR11, however, the disclosed concepts are not limited thereto, and a plurality of first photodiodes PD11 may be disposed in the first pixel region PXR11.

The first floating diffusion region FD11 may extend in the fourth direction D4 from the center CP of the pixel group PXG toward the center of the first pixel PX11.

In example embodiments, the first floating diffusion region FD11 may include a first extension portion and a second extension portion, and the first and second extension portions may be sequentially disposed from the center CP of the pixel group in the fourth direction D4. In example embodiments, the second extension portion of the first floating diffusion region FD11 may be disposed between the first and second vertical transfer gates VTG1 and VTG2. In example embodiments, a first width in the fifth direction D5 of the first extension portion of the first floating diffusion region FD11 may be greater than a second width in the fifth direction D5 of the second extension portion of the first floating diffusion region FD11.

The first pad pattern PP11 may be disposed on the first floating diffusion region FD11. The first pad pattern PP11 may overlap the first floating diffusion region FD11 in the third direction D3.

The first pad pattern PP11 may extend in the fourth direction D4 from the center CP of the pixel group PXG toward the center of the first pixel PX11.

In example embodiments, the first pad pattern PP11 may include a third extension portion and a fourth extension portion, and the third and fourth extension portions may be sequentially disposed from the center CP of the pixel group in the fourth direction D4. In example embodiments, the fourth extension portion of the first pad pattern PP11 may be disposed between the first and second vertical transfer gates VTG1 and VTG2. In example embodiments, a third width in the fifth direction D5 of the third extension portion of the first pad pattern PP11 may be greater than a fourth width in the fifth direction D5 of the fourth extension portion of the first pad pattern PP11

In example embodiments, the third width in the fifth direction D5 of the third extension portion of the first pad pattern PP11 may be less than the first width in the fifth direction D5 of the first extension portion of the first floating diffusion region FD11, and the fourth width in the fifth direction D5 of the fourth extension portion of the first pad pattern PP11 may be less than the second width in the fifth direction D5 of the second extension portion of the first floating diffusion region FD11.

The first and second vertical transfer gates VTG1 and VTS2 may be disposed at respective opposite sides in the fifth direction D5 of the first pad pattern PP1, or at respective opposite sides in the fifth direction D5 of the first floating diffusion region FD11. In example embodiments, the first and second vertical transfer gates VTG1 and VTG2 may be symmetric with respect to a diagonal line that penetrates through the center CP of the pixel group PXG and extends in the fourth direction D4. The first and second vertical transfer gates VTG1 and VTG2 may have substantially the same structure, and hereinafter, only the first vertical transfer gate VTG1 is illustrated.

The first vertical transfer gate VTG1 may include a first gate insulation pattern 31, a first gate electrode 33, a first gate capping pattern 35 and a first gate spacer 37.

The first gate electrode 33 may include a buried portion 33a extending into the inside of the substrate 10 from the first surface 12 in the third direction D3, and a protrusion portion 33b that is disposed on the buried portion 33a and having an upper surface higher than the first surface 12 of the substrate 10. The first gate insulation pattern 31 may cover a sidewall and a lower surface of the buried portion 33a of the first gate electrode 33 and a lower surface of the protrusion portion 33b of the first gate electrode 33. The first gate capping pattern 35 may be disposed on an upper surface of the first gate electrode 33. The first gate spacer 37 may cover sidewalls of the first gate insulation pattern 31, the protrusion portion 33b of the first gate electrode 33 and the first gate capping pattern 35.

The first gate insulation pattern 31 may include an oxide, e.g., silicon oxide. The first gate electrode 33 may include, e.g., doped polysilicon, a metal silicide, a metal nitride, a metal, etc. The first gate capping pattern 35 may include an oxide, e.g., silicon oxide. The first gate spacer 37 may include an insulating nitride, e.g., silicon nitride.

In example embodiments, the first pixel gate PG11 may face the first and second vertical transfer gates VTG1 and VTG2 in the fourth direction D4 in the first pixel region PXR11.

The first pixel gate PG11 may include a second gate insulation pattern, a second gate electrode and a second capping pattern sequentially stacked on the first surface 12 of the substrate 10, and a second gate spacer covering sidewalls of the second gate insulation pattern, the second gate electrode and the second capping pattern.

In example embodiments, the first pixel gate PG11 and the source/drain region adjacent thereto may collectively form the first reset transistor.

The second gate insulation pattern may include an oxide, e.g., silicon oxide. The second gate electrode may include, e.g., doped polysilicon, a metal silicide, a metal nitride, a metal, etc. The second gate capping pattern may include an oxide, e.g., silicon oxide. The second gate spacer may include an insulating nitride, e.g., silicon nitride.

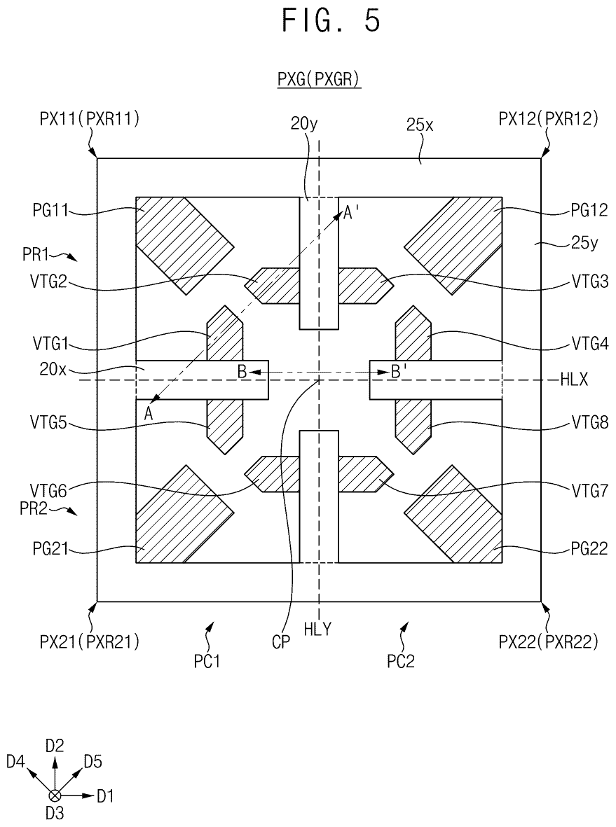

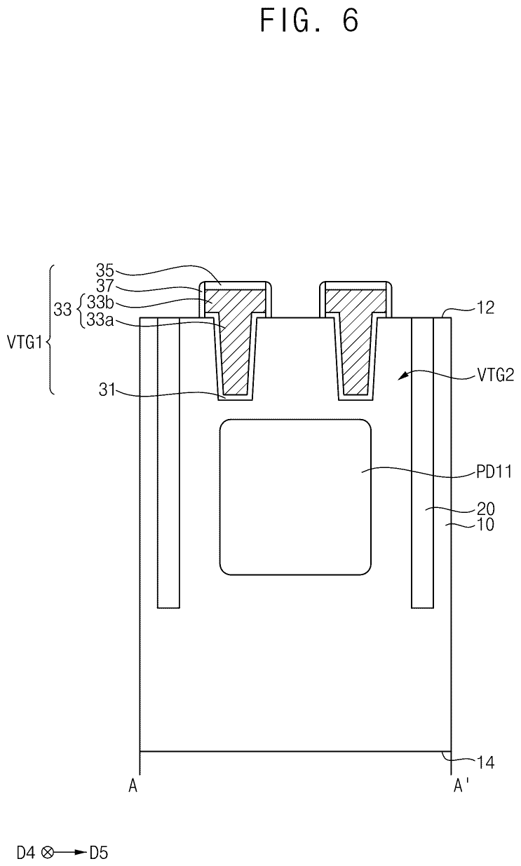

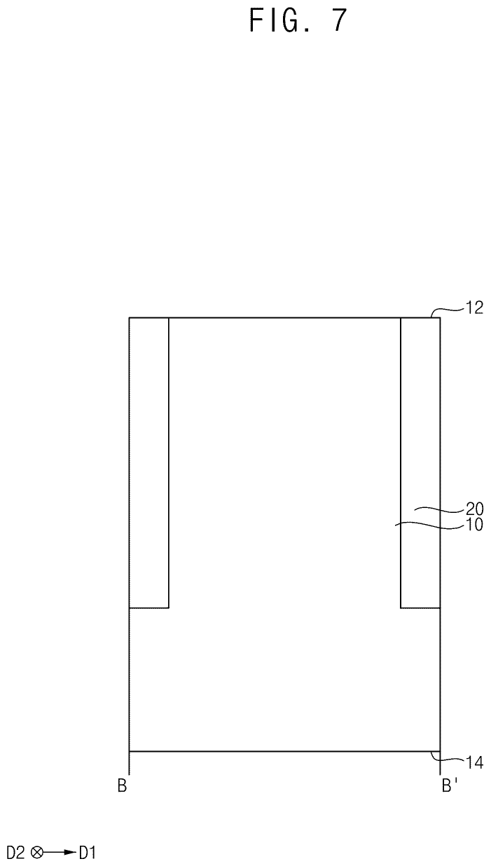

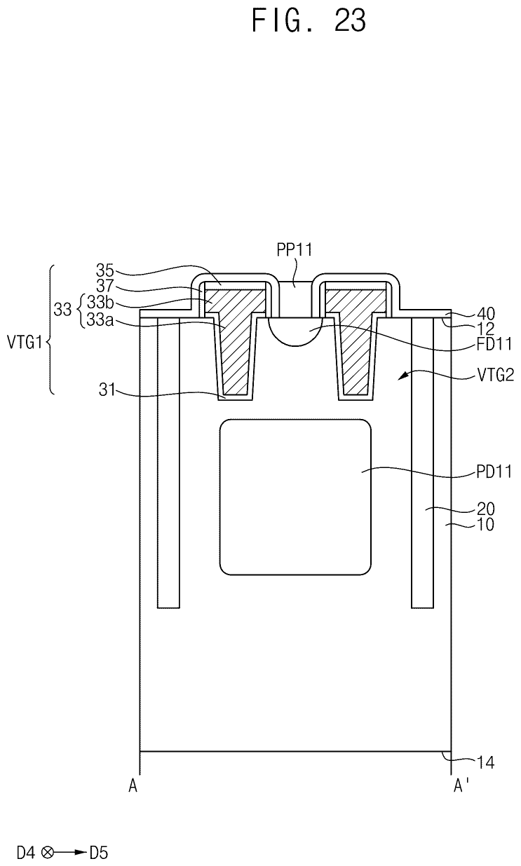

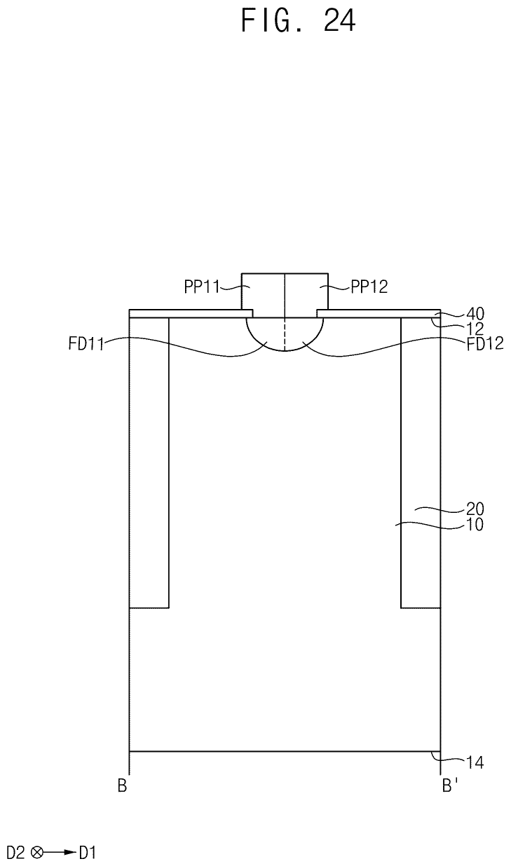

FIGS. 5 to 24 are plan views and cross-sectional views illustrating a method of manufacturing an image sensor in accordance with example embodiments. Particularly, FIGS. 5, 10, 17 and 22 are the plan views, FIGS. 6, 8, 11, 13, 15, 18, 20 and 23 are cross-sectional views taken along lines A-A′ of corresponding plan views, respectively, and FIGS. 7, 9, 12, 14, 16, 19, 21 and 24 are cross-sectional views taken along lines B-B′ of corresponding plan views, respectively.

Referring to FIGS. 5 to 7, an upper portion of a substrate 100 including first, second, third and fourth pixel regions PXR11, PXR12, PXR21 and PXR22 may be partially removed to form a first trench.

A division structure 30 may be formed in the first trench. The division structure 30 may include an inter-group division structure 25 and an inter-pixel division structure 20.

Unit pixel regions in which unit pixels are respectively formed may be defined by the division structure 30 in the substrate 10. In some cases, the unit pixel regions may also include spaces over and under the substrate 10.

N-type impurities may be doped into the substrate 10 to form first, second, third and fourth photodiodes PD11, PD12, PD21 and PD22 in the first, second, third and fourth pixel regions PXR11, PXR12, PXR21 and PXR22, respectively.

A first sub-gate insulation layer may be formed on the first surface 12 of the substrate 10.

Second trenches may be formed through the first sub-gate insulation layer and the upper portion of the substrate 10. A second sub-gate insulation layer covering a bottom and a sidewall of each of the second trenches and a buried portion 33a of a first gate electrode 33 may be formed in each of the second trenches. The first and second sub-gate insulation layers may be referred to as a gate insulation layer.

A gate electrode layer and a gate capping layer may be sequentially formed on the gate insulation layer and the buried portion 33a of the second gate electrode 33. An etching process may be performed on the gate capping layer, the gate electrode layer and the gate insulation layer.

By the etching process, the gate insulation layer may be divided into first gate insulation patterns 31 each of which may cover a lower surface and a sidewall of the buried portion 33a of the first gate electrode 33, and the gate electrode layer and the gate capping layer may be divided into protrusion portions 33b of the first gate electrodes 33 and first gate capping patterns 35, respectively.

The first gate insulation pattern 31, the buried portion 33a and the protrusion portion 33b of the first gate electrode 33 and the first gate capping pattern 35 may collectively form vertical transfer gates, for example, first to eighth vertical transfer gates VTG1, VTG2, VTG3, VTG4, VTG5, VTG6, VTG7 and VTG8.

Additionally, by the etching process, portions of the gate insulation layer, the gate electrode layer and the gate capping layer may be divided into second gate insulation patterns, second gate electrodes and second gate capping patterns, respectively.

The second gate insulation pattern, the second gate electrode and the second gate capping pattern may collectively form pixel gates, for example, first to fourth gates PG11, PG12, PG21 and PG22.

A first gate spacer 37 may be formed on a sidewall of each of the first to eighth vertical transfer gates VTG1, VTG2, VTG3, VTG4, VTG5, VTG6, VTG7 and VTG8, and hereinafter, the first gate spacer 37 may be regarded as a portion of each of the first to eighth vertical transfer gates VTG1, VTG2, VTG3, VTG4, VTG5, VTG6, VTG7 and VTG8.

Additionally, a second gate spacer may be formed on a sidewall of each of the first to fourth pixel gates PG11, PG12, PG21 and PG22, and hereinafter, the second gate spacer may be regarded as a portion of each of the first to fourth pixel gates PG11, PG12, PG21 and PG22.

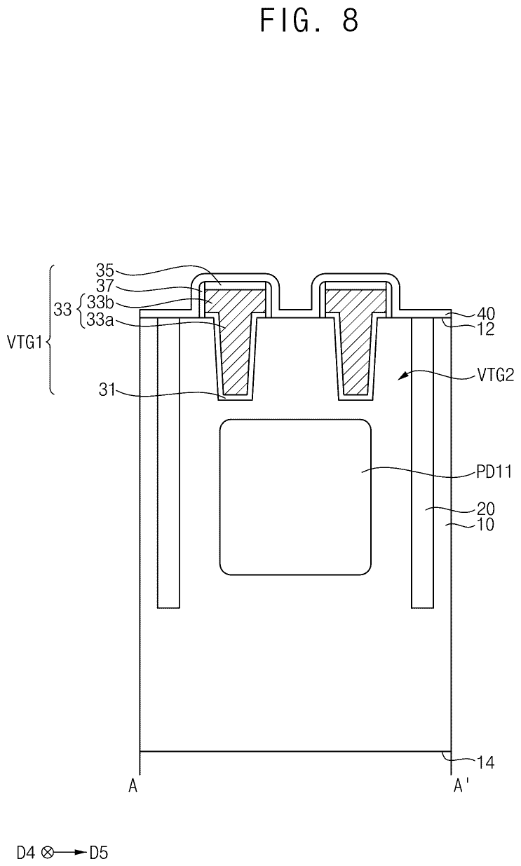

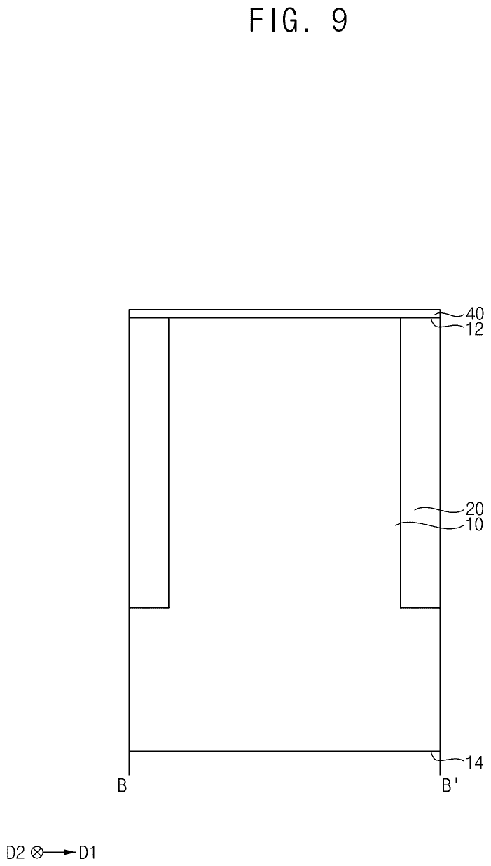

Referring to FIGS. 8 and 9, an etch stop layer 40 may be formed on the first surface 12 of the substrate 10, an upper surface of the division structure 30, upper surfaces and sidewalls of the first to eighth vertical transfer gates VTG1, VTG2, VTG3, VTG4, VTG5, VTG6, VTG7 and VTG8, and upper surfaces and sidewalls of the first to fourth pixel gates PG11, PG12, PG21 and PG22.

The etch stop layer 40 may be conformally formed. The etch stop layer 40 may include an oxide, e.g., silicon oxide.

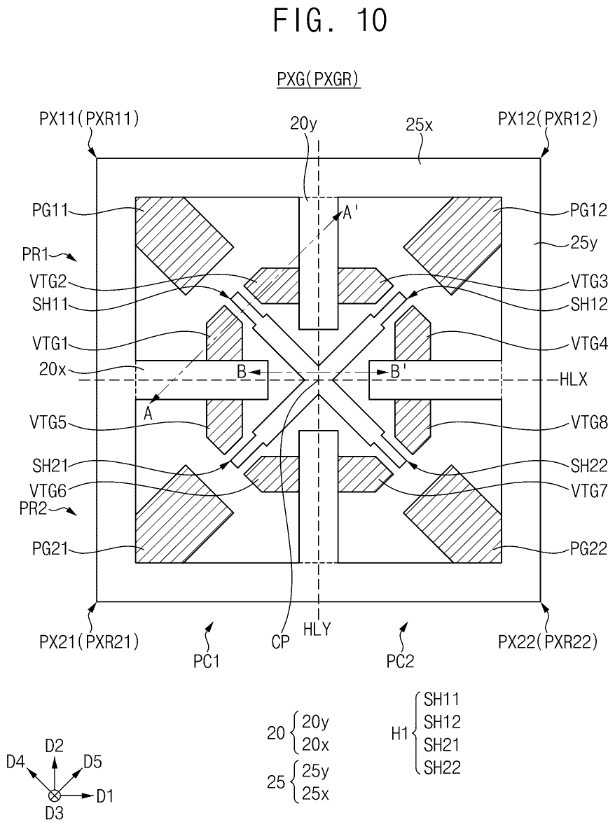

Referring to FIGS. 10 to 12, a first photoresist PR1 having a first opening H1 at least partially exposing an upper surface of the etch stop layer 40 may be formed on the etch stop layer 40.

The first opening H1 may include first, second, third and fourth sub-openings SH11, SH12, SH21 and SH22 on the first, second, third and fourth pixel regions PXR11, PXR12, PXR21 and PXR22, respectively. The first to fourth sub-openings SH11, SH12, SH21 and SH22 may be connected to one another at a center CP of a pixel group region PXGR.

In example embodiments, the first sub-opening SH11 may extend in the fourth direction D4 from the center CP of the pixel group region PXGR toward a center of the first pixel region PXR11. The second sub-opening SH12 may extend in the fifth direction D5 from the center CP of the pixel group region PXGR toward a center of the second pixel region PXR12. The third sub-opening SH21 may extend in the fifth direction D5 from the center CP of the pixel group region PXGR toward a center of the third pixel region PXR21. The fourth sub-opening SH22 may extend in the fourth direction D4 from the center CP of the pixel group region PXGR toward a center of the fourth pixel region PXR22. Thus, the first opening H1 including the first, second, third and fourth sub-openings SH11, SH12, SH21 and SH22 may have a shape of an “X” in a plan view.

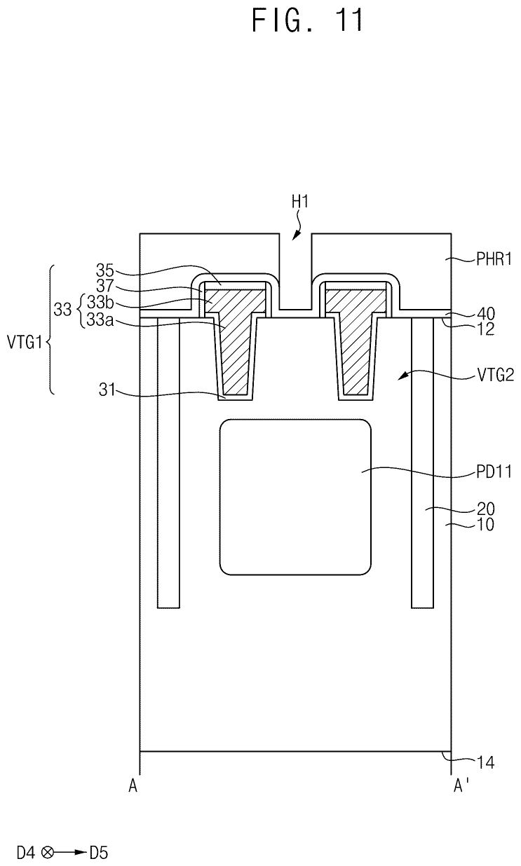

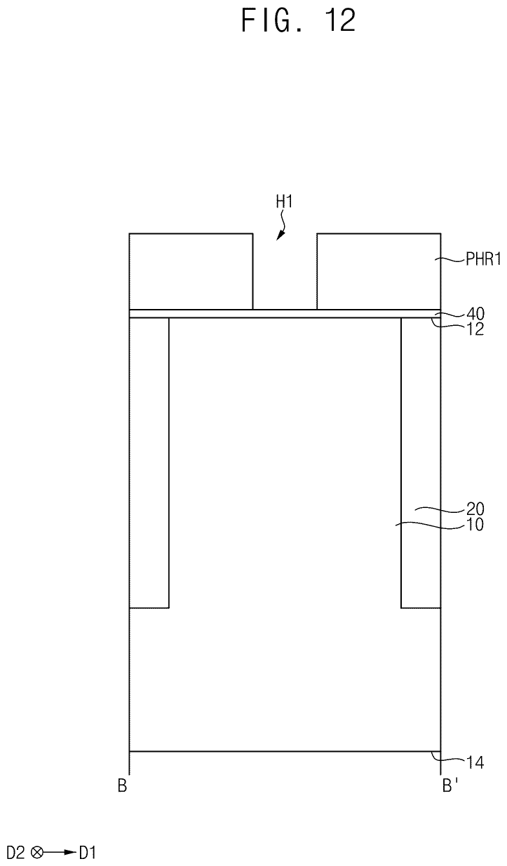

FIGS. 11 and 12 show that a first photoresist PHR1 is a single layer, however, the disclosed concepts are not limited thereto, and in some cases, may have a multi-layered structure.

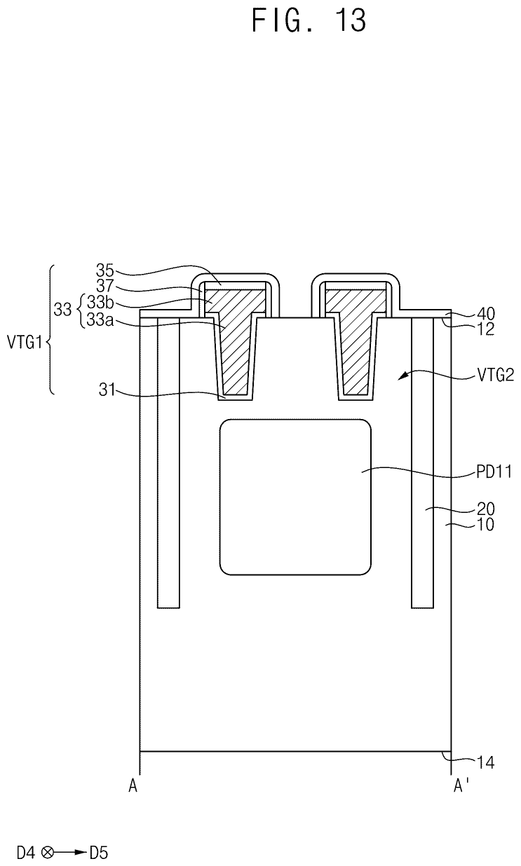

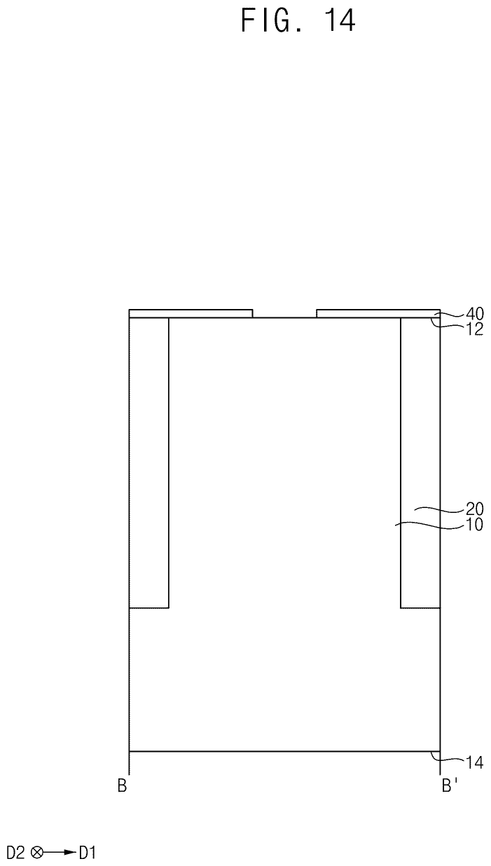

Referring to FIGS. 13 and 14, a portion of the etch stop layer 40 exposed by the first opening H1 of the first photoresist PHR1, and thus the first surface 12 of the substrate 10 may be exposed.

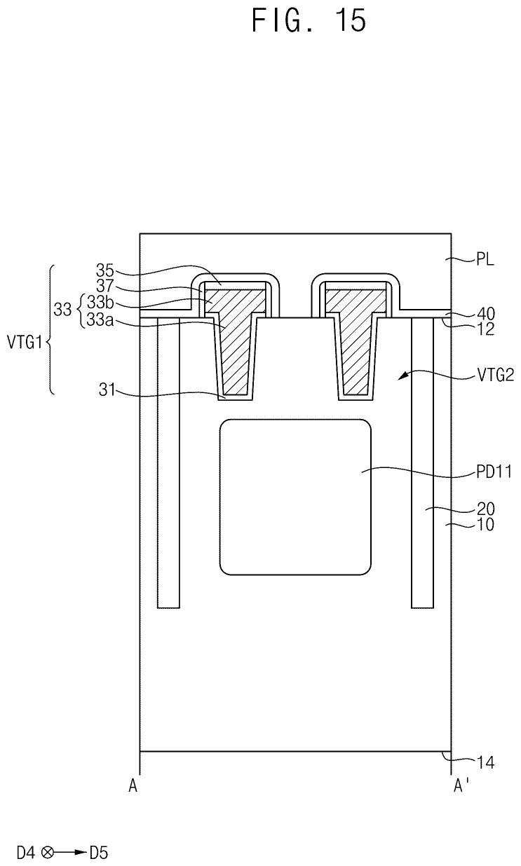

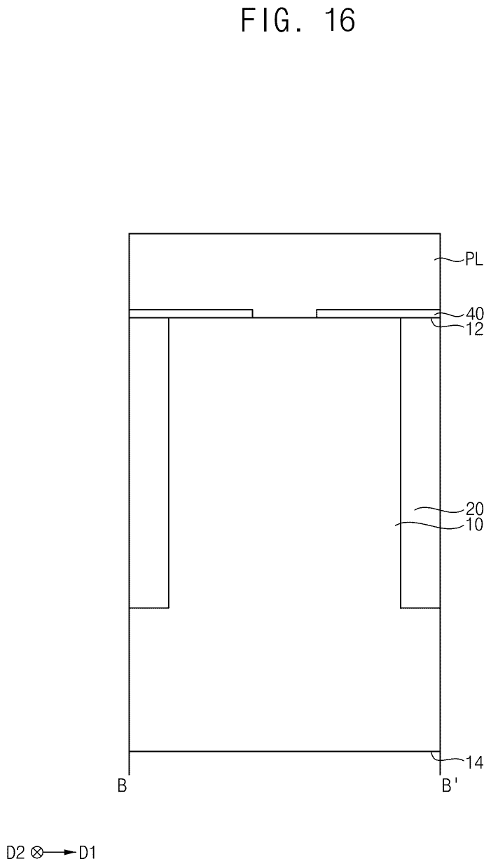

Referring to FIGS. 15 and 16, a pad layer PL may be formed on the first surface 12 of the substrate 10 and the etch stop layer 40 covering the first to eighth vertical transfer gates VTG1, VTG2, VTG3, VTG4, VTG5, VTG6, VTG7 and VTG8, and the first to fourth pixel gates PG11, PG12, PG21 and PG22 to fill the first opening H1.

In example embodiments, an upper surface of the pad layer PL may be higher than an uppermost surface of the etch stop layer 40.

In example embodiments, the pad layer PL may be formed by, e.g., a chemical vapor deposition (CVD) process, a low pressure chemical vapor deposition (LP-CVD) process, etc.

The pad layer PL may include polysilicon doped with first impurities, e.g., n-type impurities.

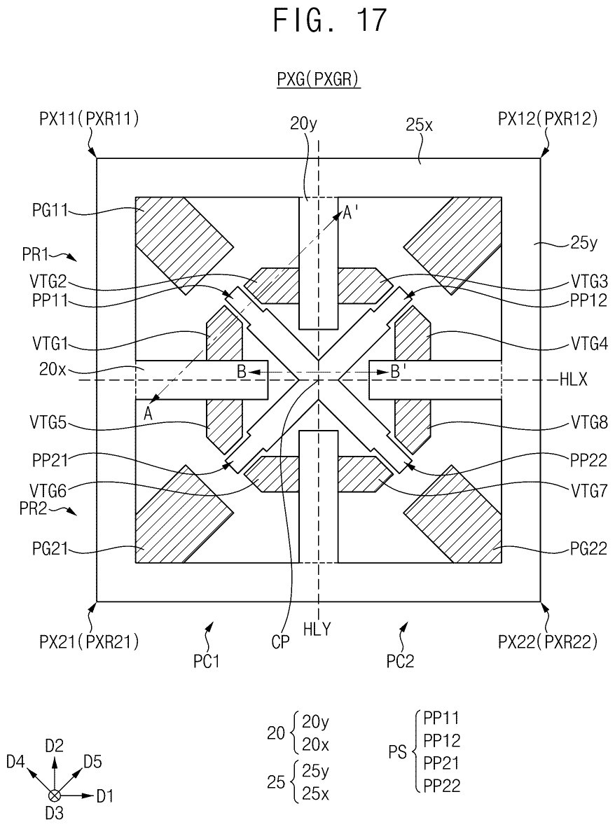

Referring to FIGS. 17 to 19, a second photoresist PHR2 may be formed on the pad layer PL.

The second photoresist PHR2 may at least partially overlap the first opening H1 in the third direction D3.

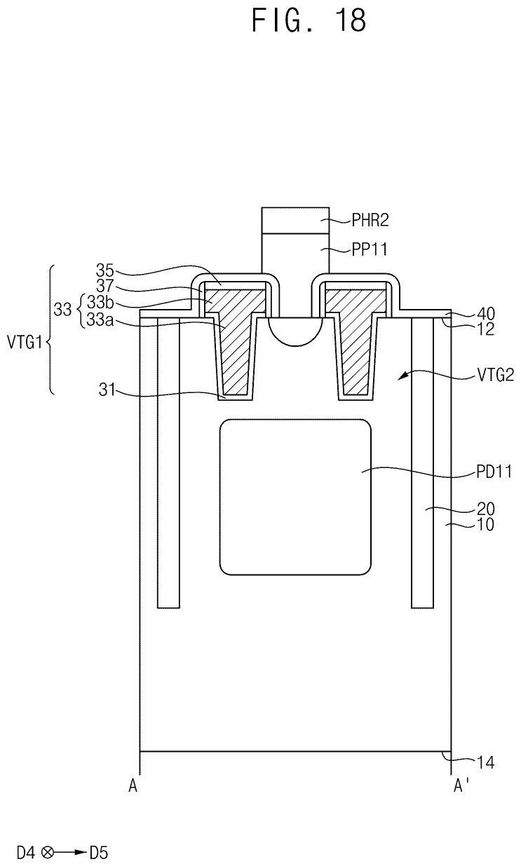

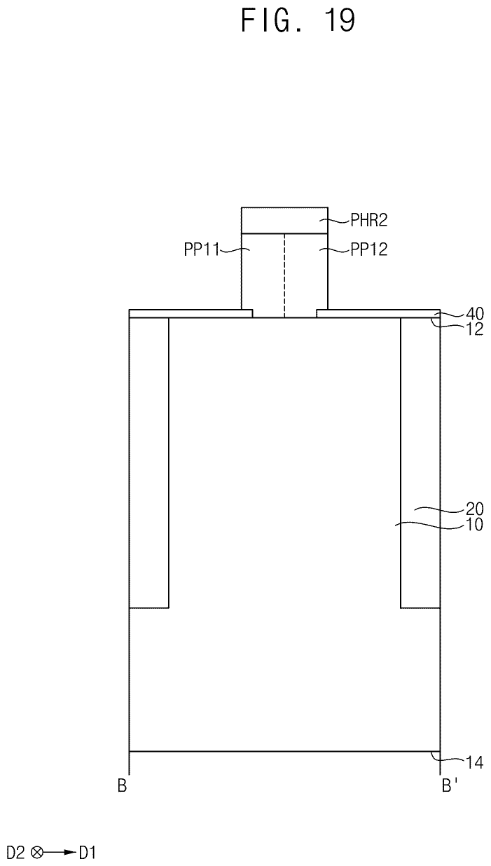

FIGS. 18 and 19 show that the second photoresist PHR2 is a single layer, however, the disclosed concepts are not limited thereto, and in some cases, may have a multi-layered structure.

The pad layer PL may be etched using the second photoresist PHR2 as an etching mask so that the pad layer PL may be transformed into a pad structure PS.

The pad structure PS may include first, second, third and fourth pad patterns PP11, PP12, PP21 and PP22 in the first, second, third and fourth sub-openings SH11, SH12, SH21 and SH22, respectively.

The pad structure PS including the first, second, third and fourth pad patterns PP11, PP12, PP21 and PP22 may have a shape of an “X” in a plan view, corresponding to the shape of the first opening H1. That is, the first pad pattern PP11 may extend in the fourth direction D4 from the center CP of the pixel group region PXGR toward the center of the first pixel region PXR11. The second pad pattern PP12 may extend in the fifth direction D5 from the center CP of the pixel group region PXGR toward the center of the second pixel region PXR12. The third pad pattern PP21 may extend in the fifth direction D5 from the center CP of the pixel group region PXGR toward the center of the third pixel region PXR21. The fourth pad pattern PP22 may extend in the fourth direction D4 from the center CP of the pixel group region PXGR toward the center of the fourth pixel region PXR22.

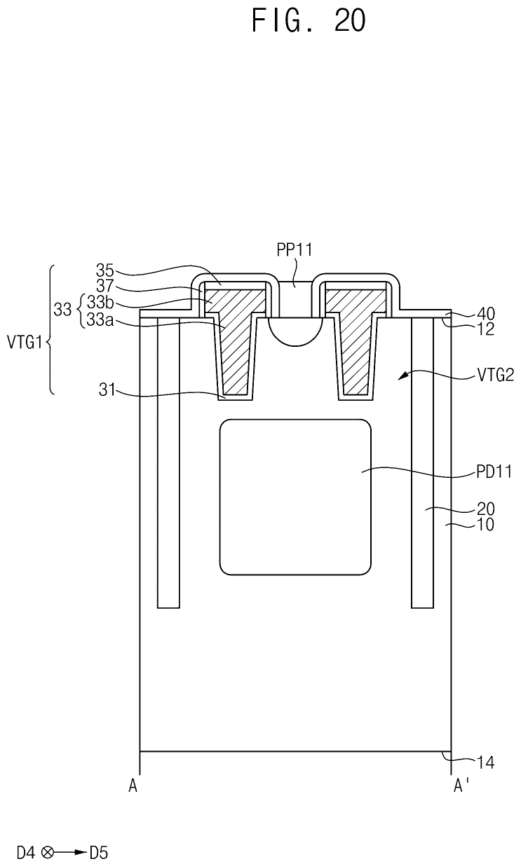

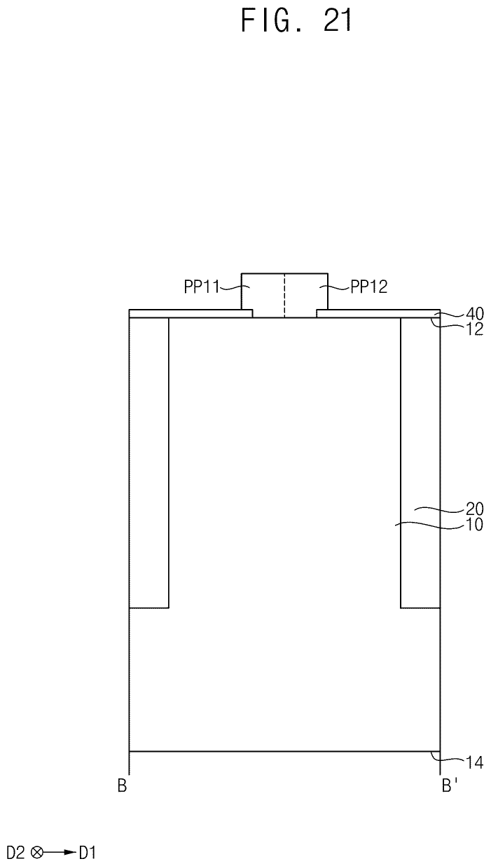

Referring to FIGS. 20 and 21, the second photoresist PHR2 may be removed.

An etch back process may be performed on an upper portion of the pad structure PS. In example embodiments, an upper surface of the pad structure PS may be lower than the uppermost surface of the etch stop layer 40.

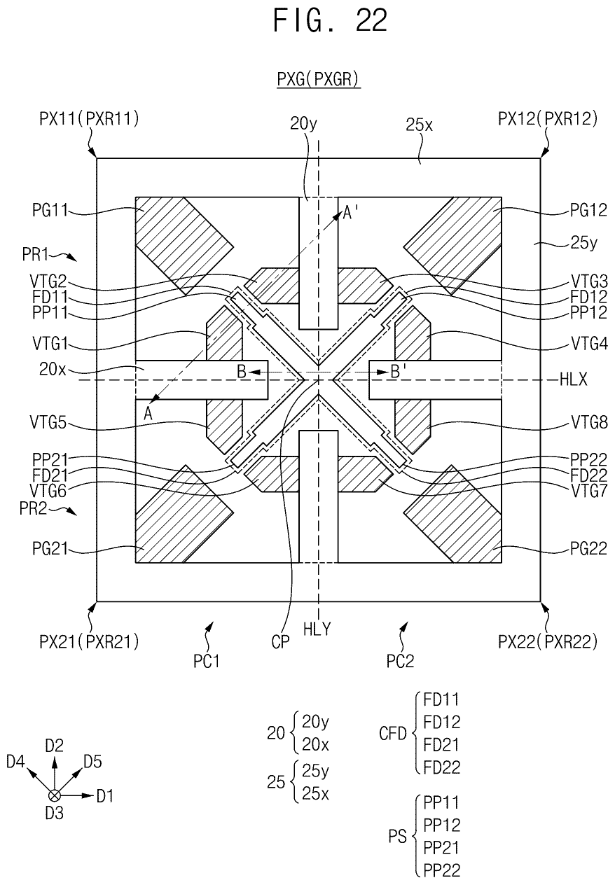

Referring to FIGS. 22 to 24, an annealing process may be performed so that the first impurities of the pad structure PS may diffuse into the upper portion of the substrate 10 through the first surface 12 of the substrate 10.

Accordingly, a common floating diffusion region CFD may be formed under the pad structure PS.

The common floating diffusion region CFD may include first, second, third and fourth floating diffusion region FD11, FD12, FD21 and FD22. The common floating diffusion region CFD may have a shape of an “X” in a plan view, corresponding to the shape of the pad structure PS.

Thus, the first floating diffusion region FD11 may extend in the fourth direction D4 from the center CP of the pixel group region PXGR toward the center of the first pixel region PXR11. The second floating diffusion region FD12 may extend in the fifth direction D5 from the center CP of the pixel group region PXGR toward the center of the second pixel region PXR12. The third floating diffusion region FD21 may extend in the fifth direction D5 from the center CP of the pixel group region PXGR toward the center of the third pixel region PXR21. The fourth floating diffusion region FD22 may extend in the fourth direction D4 from the center CP of the pixel group region PXGR toward the center of the fourth pixel region PXR22.

Each of the first to fourth floating diffusion regions FD11, FD12, FD21 and FD22 may further include the first impurities diffused from the pad structure PS.

Referring to FIGS. 1 to 4 again, an insulating interlayer 60 may be formed on the etch stop layer 40 and the pad structure PS.

Second openings may be formed through the insulating interlayer 60 to expose upper surfaces of the first, second, third and fourth pad patterns PP11, PP12, PP21 and PP22, respectively. First, second, third and fourth contact plugs CT11, CT12, CT21 and CT22 may be formed in the second openings to contact the upper surfaces of the first, second, third and fourth pad patterns PP11, PP12, PP21 and PP22, respectively.

By the above processes, the image sensor may be manufactured.

In the method of manufacturing the image sensor, the common floating diffusion region CFD may be formed by the annealing process on the pad structure PS including the first impurities. The common floating diffusion region CFD may have a smaller volume when compared to a case in which an ion implantation process is performed on the first surface 12 of the substrate 10 to form the common floating diffusion region CFD, so that the capacitance of the common floating diffusion CFD may decrease. Accordingly, charge-to-voltage conversion efficiency in the common floating diffusion region CFD, that is, a conversion gain may be improved.

Additionally, the first to fourth contact plugs CT11, CT12, CT21 and CT22 may not contact the common floating diffusion region CFD but may contact the upper surfaces of the first to fourth pad patterns PP11, PP12, PP21 and PP22. Thus, the first surface 12 of the substrate 10 may not be exposed to an etching solution during the etching process for forming the first to fourth contact plugs CT11, CT12, CT21 and CT22, so as not to be damaged. Accordingly, leakage current due to the damage of the substrate 10 may be reduced.

Furthermore, the common floating diffusion region CFD may have a shape of an “X” in a plan view. Thus, the common floating diffusion region CFD may have a smaller volume when compared to a case in which the common floating diffusion region CFD has the same width in the first and second directions D1 and D2. Accordingly, the charge-to-voltage conversion efficiency in the common floating diffusion region CFD may be improved.

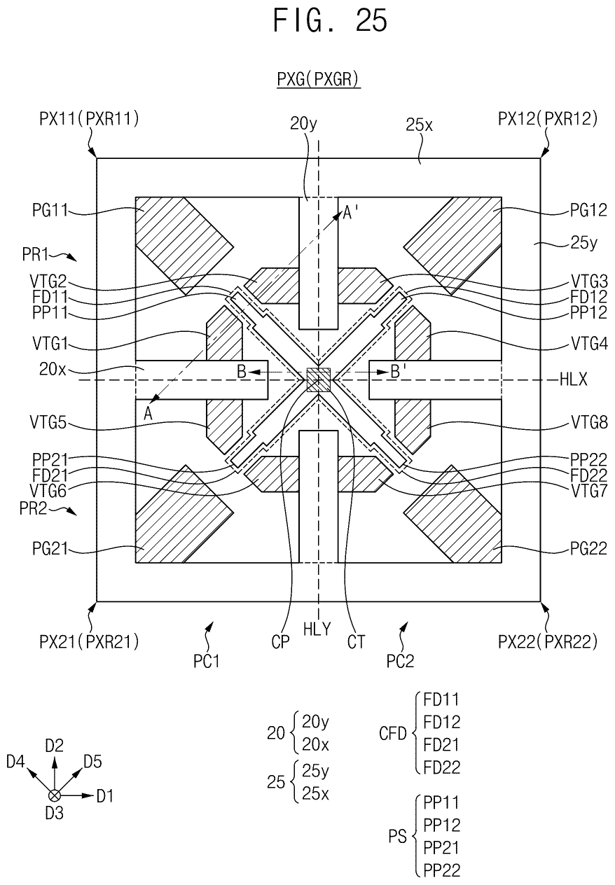

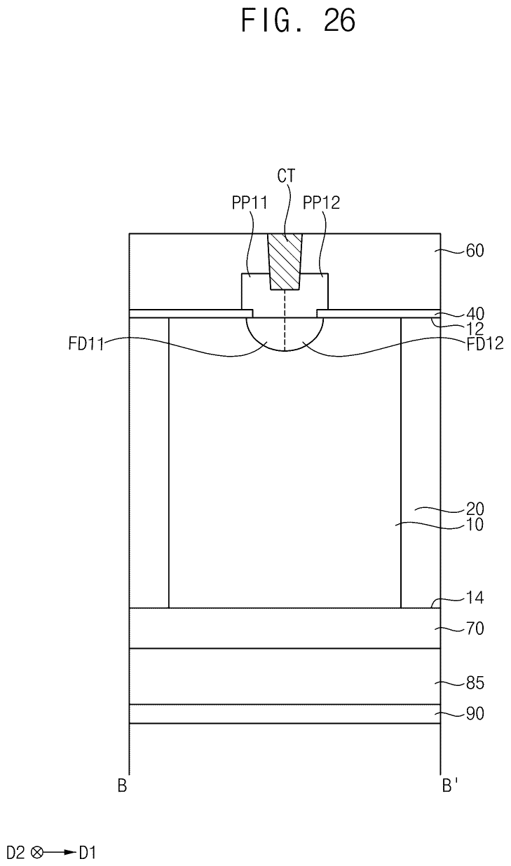

FIGS. 25 and 26 are a plan view and a cross-sectional view, respectively, illustrating an image sensor in accordance with example embodiments, which may correspond to FIGS. 1 and 4, respectively. This image sensor may be substantially the same as or similar to that of FIGS. 1 to 4, except for including a fifth contact plug CT instead of the first to fourth contact plugs CT11, CT12, CT21 and CT22.

Referring to FIGS. 25 and 26, the fifth contact plug CT may be disposed at the center CP of the pixel group region PXGR where the first to fourth pad patterns PP11, PP12, PP21 and PP22 are connected to one another.

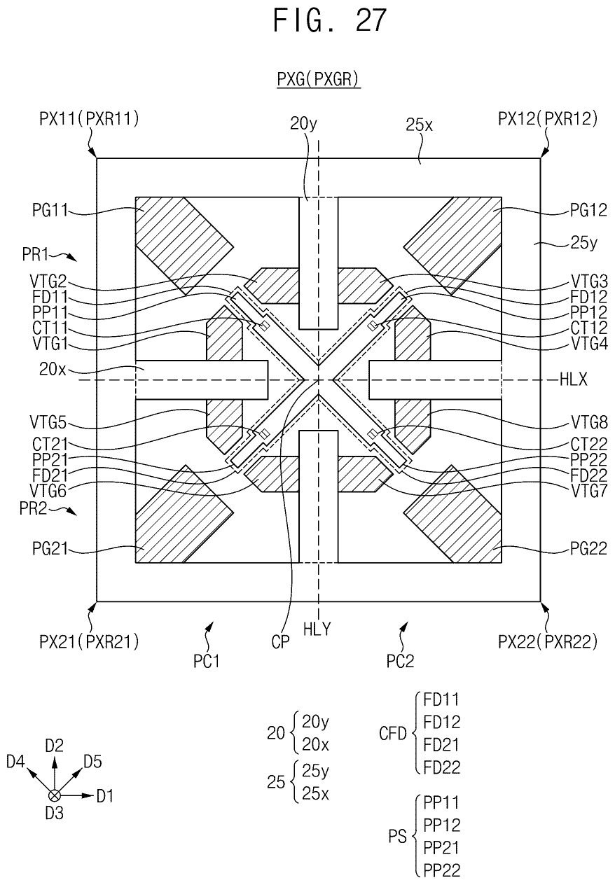

FIG. 27 is a plan view illustrating an image sensor in accordance with example embodiments, which may correspond to FIG. 1. This image sensor may be substantially the same as or similar to that of FIGS. 1 to 4, except for locations of the first to fourth contact plugs CT11, CT12, CT21 and CT22.

Referring to FIG. 27, the first contact plug CT11 may contact an upper surface of a second portion of the first pad pattern PP11 except for a first portion of the first pad pattern PP11 that is disposed between sidewalls of the first and second vertical transfer gates VTG1 and VTG2.

Likewise, the second contact plug CT12 may contact an upper surface of a second portion of the second pad pattern PP12 except for a first portion of the second pad pattern PP11 that is disposed between sidewalls of the third and fourth vertical transfer gates VTG3 and VTG4. The third contact plug CT21 may contact an upper surface of a second portion of the third pad pattern PP21 except for a first portion of the third pad pattern PP21 that is disposed between sidewalls of the fifth and sixth vertical transfer gates VTG5 and VTG6. The fourth contact plug CT22 may contact an upper surface of a second portion of the fourth pad pattern PP22 except for a first portion of the fourth pad pattern PP22 that is disposed between sidewalls of the seventh and eighth vertical transfer gates VTG7 and VTG8.

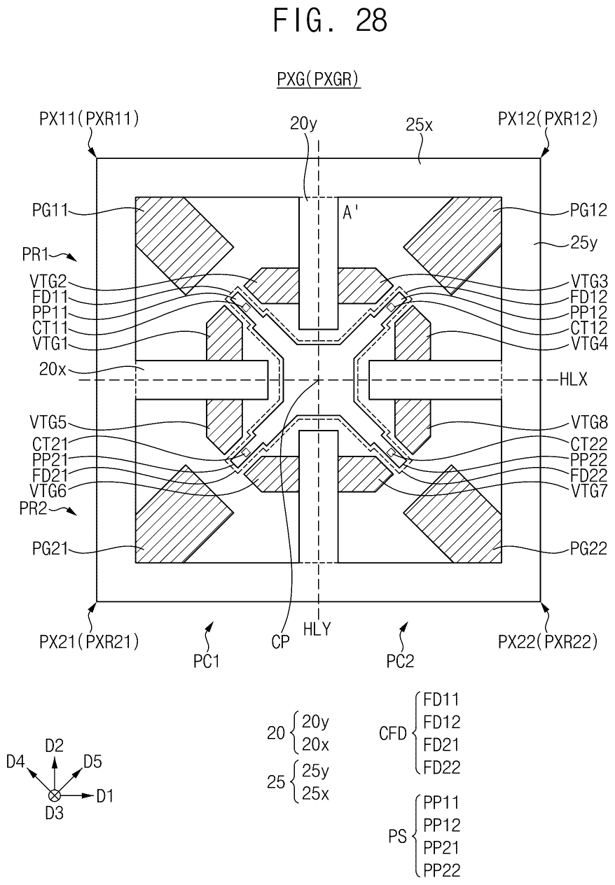

FIG. 28 is a plan view illustrating an image sensor in accordance with example embodiments, which may correspond to FIG. 1. This image sensor may be substantially the same as or similar to that of FIGS. 1 to 4, except for shapes of the common floating diffusion region CFD and the pad structure PS.

Referring to FIG. 28, the pad structure PS may include a first central portion having a shape of a rectangle and disposed at the center CP of the pixel group region PXG in a plan view, and first to fourth extension portions extending toward the centers of the first to fourth pixel regions PXR11, PXR12, PXR21 and PXR22, respectively.

The common floating diffusion region CFD may include a second central portion and fifth to eighth extension portions extending toward the centers of the first to fourth pixel regions PXR11, PXR12, PXR21 and PXR22, respectively. The second central portion and the fifth to eighth extension portions of the common floating diffusion region CFD may overlap the first central portion and the first to fourth extension portions, respectively, of the pixel structure PS.

FIG. 28 shows that the first to fourth contact plugs CT11, CT12, CT21 and CT22 contact upper surfaces of the first to fourth extension portions, respectively, of the pad structure PS, however, the disclosed concepts are not limited thereto. For example, the image sensor may include the fifth contact plug CT instead of the first to fourth contact plugs CT11, CT12, CT21 and CT22, and in this case, the fifth contact plug CT may contact an upper surface of the first central portion of the pad structure PS.

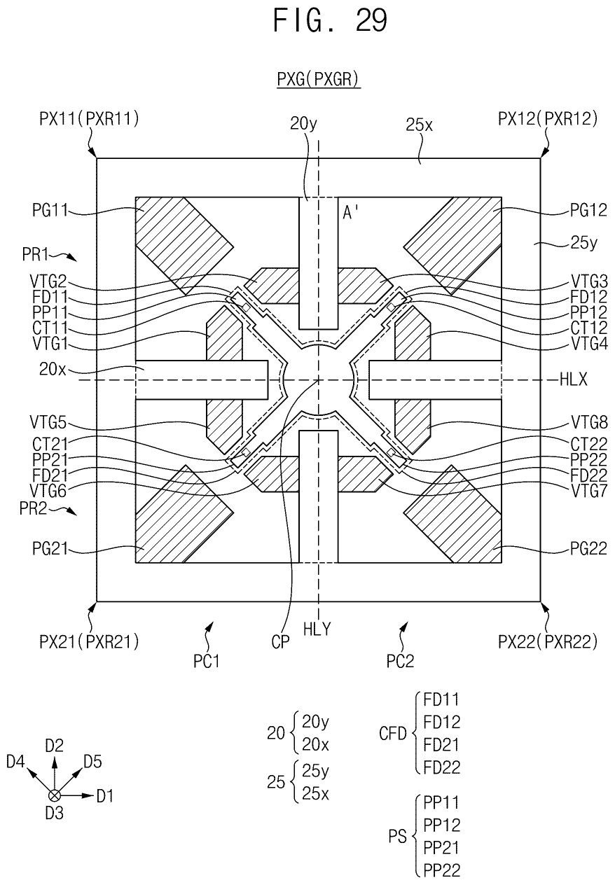

FIG. 29 is a plan view illustrating an image sensor in accordance with example embodiments, which may correspond to FIG. 28. This image sensor may be substantially the same as or similar to that of FIG. 28, except for shapes of the common floating diffusion region CFD and the pad structure PS.

Referring to FIG. 29, the first central portion of the common floating diffusion region CFD may have a shape of, e.g., a circle or an ellipse in a plan view.

However, the shape of the first central portion of the common floating diffusion region CFD is not limited to the shape of the rectangle, the circle or the ellipse.

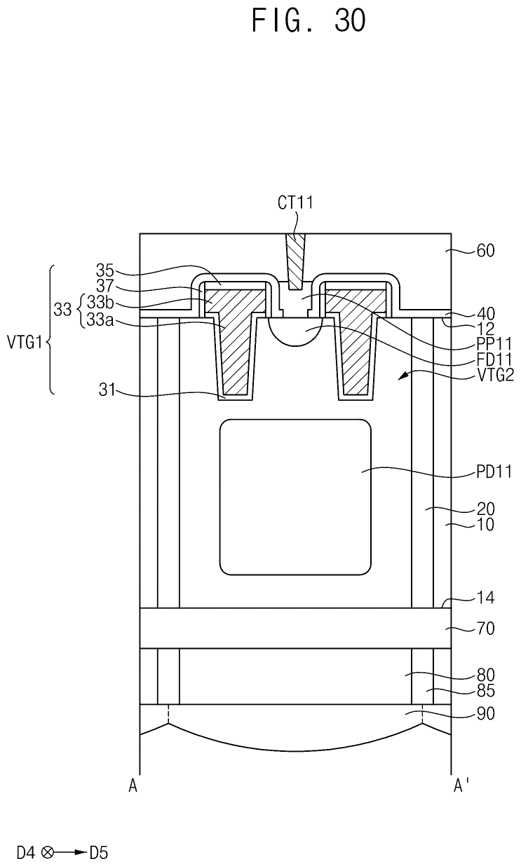

FIG. 30 is a cross-sectional view illustrating an image sensor in accordance with example embodiments, which may correspond to FIG. 3. This image sensor may be substantially the same as or similar to that of FIGS. 1 to 4, except for the shape of a cross-section of the pad structure PS.

Referring to FIG. 30, in a cross-sectional view along the fifth direction D5 of a portion of the first pad pattern PP11 between sidewalls of the first and second vertical transfer gates VTG1 and VTG2 opposite to one another in the fifth direction D5, a width of a lower portion of the first pad pattern PP11 in the fifth direction D5 may be less than a width of an upper portion of the first pad pattern PP11 in the fifth direction D5.

Portions of the etch stop layer 40 covering the sidewalls of the first and second vertical transfer gates VTG1 and VTG2 opposite to one another in the fifth direction D5 may have an “L” shape.

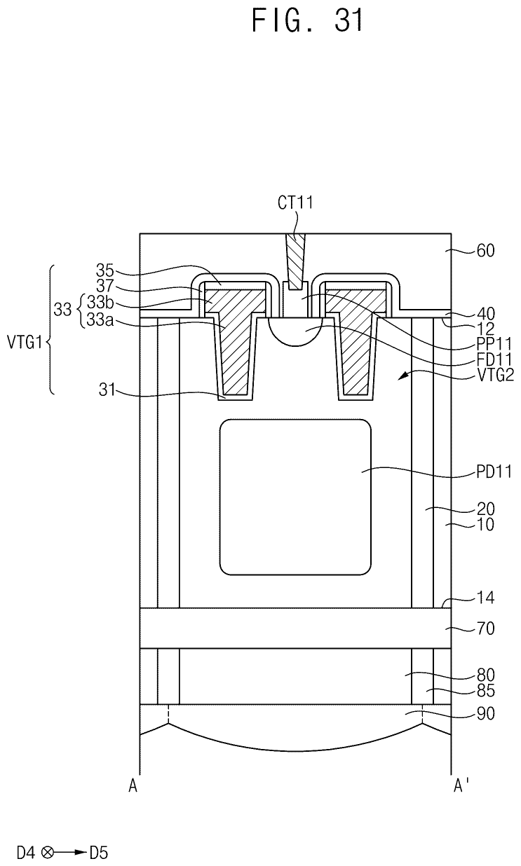

FIG. 31 is a cross-sectional view illustrating an image sensor in accordance with example embodiments, which may correspond to FIG. 3. This image sensor may be substantially the same as or similar to that of FIGS. 1 to 4, except for the shape of the pad structure PS.

Referring to FIG. 31, the portion of the first pad pattern PP11 between the sidewalls of the first and second vertical transfer gates VTG1 and VTG2 opposite to one another in the fifth direction D5 may be spaced apart from and may not contact the portions of the etch stop layer 40 covering the sidewalls of the first and second vertical transfer gates VTG1 and VTG2 opposite to one another in the fifth direction D5.

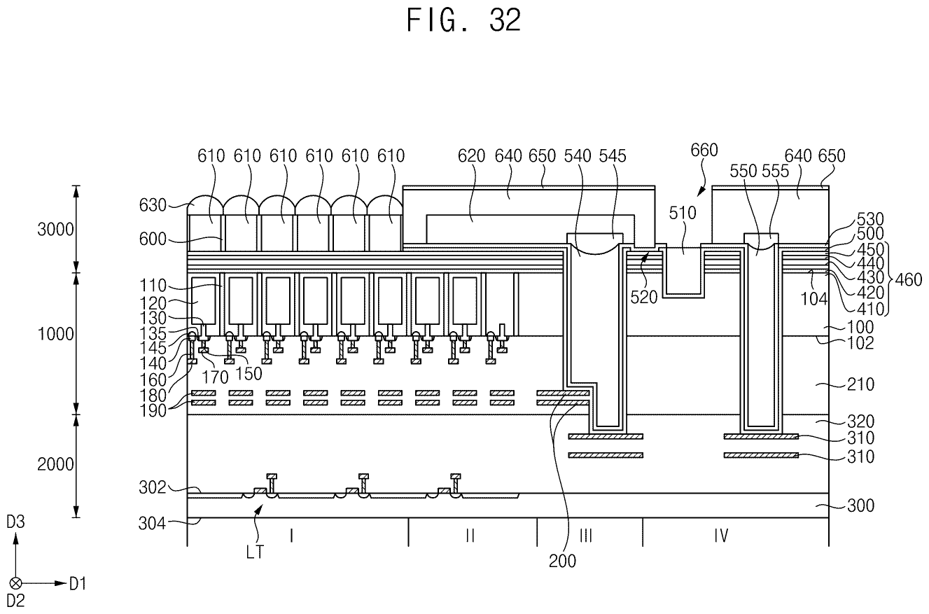

FIG. 32 is a cross-sectional view illustrating an image sensor in accordance with example embodiments. This image sensor may include elements such as the vertical transfer gates, the floating diffusion regions, the pad structures, etc., that are substantially the same as or similar to those of FIGS. 1 to 4, and thus repeated explanations thereof are omitted herein.

Referring to FIG. 32, the image sensor may include a logic circuit structure 2000, a photoelectric conversion circuit structure 1000 and a light transmitting structure 3000.

Additionally, the image sensor may include a pad 510 and first and second through via structures.

The photoelectric conversion circuit structure 1000 may include first, second, third and fourth regions I, II, III and IV. In example embodiments, in a plan view, the first region I may have a shape of a square or a rectangle, the second region II may surround the first region I, the fourth region IV may surround the second region II, and the third region III may be disposed in the fourth region IV, however, the disclosed concepts are not limited thereto.

In example embodiments, the first region I may be an active pixel region in which active pixels are disposed, the second region II may be an optical black (OB) region in which OB pixels are disposed, the third region III may be an extension region in which the first through via structure is disposed, and the fourth region IV may be a pad region in which the pad 510 is disposed.

Hereinafter, portions of the logic circuit structure 2000 and the light transmitting structure 3000 overlapping the first to fourth regions I, II, III and IV of the photoelectric conversion circuit structure 1000 in the third direction D3 may also be referred to as the first to fourth regions I, II, III and IV, respectively.

The photoelectric conversion circuit structure 1000 may include a first substrate 100, a division structure 110, photodiodes 120, transfer transistors, pad structures 140, pixel transistors, first and second vias 150 and 160, first to fourth wirings 170, 180, 190 and 200, and a first insulating interlayer 210.

The first substrate 100 may include a first surface 102 and a second surface 104 opposite to the first surface 102 in the third direction D3. In the figure, the first surface 102 is disposed under the second surface 104.

In example embodiments, p-type wells including p-type impurities may be disposed in a portion of the first substrate 100.

The division structure 110 may extend in the third direction D3 in the first and second regions I and II, and may have a lattice shape disposed in the first and second directions D1 and D2 in a plan view. Unit pixel regions defined by the division structure 110 may be spaced apart from one another in each of the first and second directions D1 and D2.

The photodiodes 120 may be disposed in the unit pixel regions, respectively, defined by the division structure 110 disposed in the first and second regions I and II, however, the photodiodes 120 may not be disposed in some of the unit pixel regions defined by the division structure 110 disposed in the second region II.

The photodiode 120 may be a region doped with n-type impurities in the p-type well in the first and second regions I and II, and thus the photodiode 120 and the p-type well may form a PN junction diode. In example embodiments, a highly doped p-type impurity region may be further disposed at a portion of the first substrate 100 adjacent to the division structure 110.

The transfer transistor may include a transfer gate (TG) 130, the photodiode 120, and a floating diffusion region (FD) 145 at a portion of the first substrate 100 adjacent to the TG 130. The photodiode 120 may serve as a source of the transfer transistor and the FD 145 may serve as a drain of the transfer transistor.

The TG 130 may include a buried portion extending from the first surface 102 of the first substrate 100 in the third direction D3 upwardly and a protrusion portion under the buried portion and having a lower surface lower than the first surface 102 of the first substrate 100.

The FD 145 may be disposed at a portion of the first substrate 100 adjacent to the first surface 102 and the TG 130, and may be doped with n-type impurities.

A gate spacer 135 may cover a sidewall of the TG 130. The gate spacer 135 may include an insulating nitride, e.g., silicon nitride.

The pad structure 140 may be disposed under the FD 145. The pad structure 140 may include polysilicon doped with n-type impurities.

The pixel transistors may be disposed on the first surface 102 of the first substrate 100. The pixel transistors may include, e.g., a source follower transistor, a reset transistor and a select transistor.

The first via 150 may contact the TG 130, and may be connected to the first wiring 170. The second via 160 may contact the pad structure 140, and may be connected to the second wiring 180.

Additional vias and wirings may be further disposed in the first insulating interlayer 210 in the first and second regions I and II to be electrically connected to the pixel transistors. FIG. 32 shows that each of the third and fourth wirings 190 and 200 is disposed at two levels, however, the disclosed concepts are not limited thereto.

The first insulating interlayer 210 may include an oxide, e.g., silicon oxide, or a low-k dielectric material having a dielectric constant lower than that of silicon oxide.

The light transmitting structure 3000 may include a lower planarization layer 460, a grid 600, color filters 610, a light blocking layer 620, an optical structure 630, an upper planarization layer 640 and a transparent electrode layer 650.

In example embodiments, the lower planarization layer 460 may include first, second, third, fourth and fifth layers 410, 420, 430, 440 and 450 sequentially stacked in the third direction D3. For example, the first to fifth layers 410, 420, 430, 440 and 450 may include aluminum oxide, hafnium oxide, silicon oxide, silicon nitride and hafnium oxide, respectively, but the disclosed concepts are not limited thereto.

The grid 600 may be formed on the lower planarization layer 460, and may have a lattice shape in a plan view, corresponding to the division structure 110. The grid 600 may include a low refractive index material (LRIM).

The color filters 610 may be disposed on the lower planarization layer 460.

The light blocking layer 620 may be disposed on the lower planarization layer 460, the first through via structure and a first insulation pattern 530. However, the light blocking layer 620 may not be disposed on a portion of the first insulation pattern 530 in a fourth trench 520 that may be formed by removing a portion of a conductive pattern 500 on the lower planarization layer 460 at a boundary between the third and fourth regions III and IV to expose an upper surface of the lower planarization layer 460.

The optical structure 630 may be disposed on the color filters 610 in the first region I.

The upper planarization layer 640 may be disposed on the light blocking layer 620, the first insulation pattern 530 and the second through via structure in the second, third and fourth regions II, III and IV, and may include a third opening 660 exposing an upper surface of the pad 510 in the fourth region IV.

In example embodiments, the optical structure 630 and the upper planarization layer 640 may include substantially the same material, e.g., photoresist material having a high transmittance.

The transparent electrode layer 650 may be disposed on the optical structure 630 and the upper planarization layer 640. The transparent electrode layer 650 may include, e.g., ITO, IZO, IZO, ZnO, SnO₂, antimony-doped tin oxide (ATO), antimony-doped zinc oxide (AZO), gallium-doped zinc oxide (GZO), TiO₂, fluorine-doped tin oxide (FTO), etc.

The logic circuit structure 2000 may include a second substrate 300, a second insulating interlayer 320, logic transistors LT and a fifth wiring 310.

The second substrate 300 may include a third surface 302 and a fourth surface 304 opposite to the third surface 302 in the third direction D3. FIG. 32 shows that the third surface 302 is disposed over the fourth surface 304.

The logic transistors LT may be disposed on third surface 302 of the second substrate 300.

Vias and wirings connected to the logic transistors LT may be disposed in the second insulating interlayer 320. FIG. 32 shows that the fifth wiring 310 is disposed at two levels, however, the disclosed concepts are not limited thereto.

The second insulating interlayer 320 may include an oxide, e.g., silicon oxide, or a low-k dielectric material.

The pad 510 may extend through the lower planarization layer 460 and an upper portion of the first substrate 100 in the fourth region IV. A sidewall and a lower surface of the pad 510 may be covered by the conductive pattern 500.

The pad 510 may be electrically connected to an outer wiring, and may serve as a path through which electrical signals are input into or output from the active pixel and/or the OB pixel. The pad 510 may include a metal, e.g., aluminum.

The first through via structure may extend through the lower planarization layer 460, the first substrate 100, the first insulating interlayer 210, and an upper portion of the second insulating interlayer 320 in the third region III, and may contact the fourth wiring 200 in the first insulating interlayer 210 and the fifth wiring 310 in the second insulating interlayer 320.

The first through via structure may include a first filling pattern 540 extending through the lower planarization layer 460, the first substrate 100, the first insulating interlayer 210, and the upper portion of the second insulating interlayer 320 in the third direction D3, the first insulation pattern 530 covering a sidewall and a lower surface of the first filling pattern 540, the conductive pattern 500 covering a sidewall and a lower surface of the first insulation pattern 530, and a first capping pattern 545 on an upper surface of the first filling pattern 540.

The second through via structure may extend through the lower planarization layer 460, the first substrate 100, the first insulating interlayer 210, and the upper portion of the second insulating interlayer 320 in the fourth region IV, and may contact the fifth wiring 310.

The second through via structure may include a second filling pattern 550 extending through the lower planarization layer 460, the first substrate 100, the first insulating interlayer 210, and the upper portion of the second insulating interlayer 320 in the third direction D3, the first insulation pattern 530 covering a sidewall and a lower surface of the second filling pattern 550, the conductive pattern 500 covering the sidewall and the lower surface of the first insulation pattern 530, and a second capping pattern 555 on an upper surface of the second filling pattern 550.

Each of the first and second filling patterns 540 and 550 may include, e.g., a LRIM, and each of the first and second capping patterns 545 and 555 may include, e.g., photoresist material.

A portion of the conductive pattern 500 included in the first through via structure may contact the fourth and fifth wirings 200 and 310 and may electrically connect the fourth and fifth wirings 200 and 310 to one another. A portion of the conductive pattern 500 included in the second through via structure may contact the fifth wiring 310 and may be electrically connected thereto. The conductive pattern 500 may be included in the first and second through via structures, and may also be disposed on the lower planarization layer 460 in the second, third and fourth regions II, III and IV.

The conductive pattern 500 may include a metal, e.g., tungsten. In example embodiments, a barrier pattern may be further disposed under the conductive pattern 500, and may include a metal nitride, e.g., titanium nitride.

The first insulation pattern 530 may be included in the first and second through via structures, and may also be disposed on a portion of the conductive pattern 500 on the lower planarization layer 460 in the second, third and fourth regions II, III and IV. Additionally, the first insulation pattern 530 may also be disposed in the fourth trench 520 exposing the upper surface of the lower planarization layer 460, and may contact the lower planarization layer 460. The first insulation pattern 530 may include an oxide, e.g., silicon oxide.

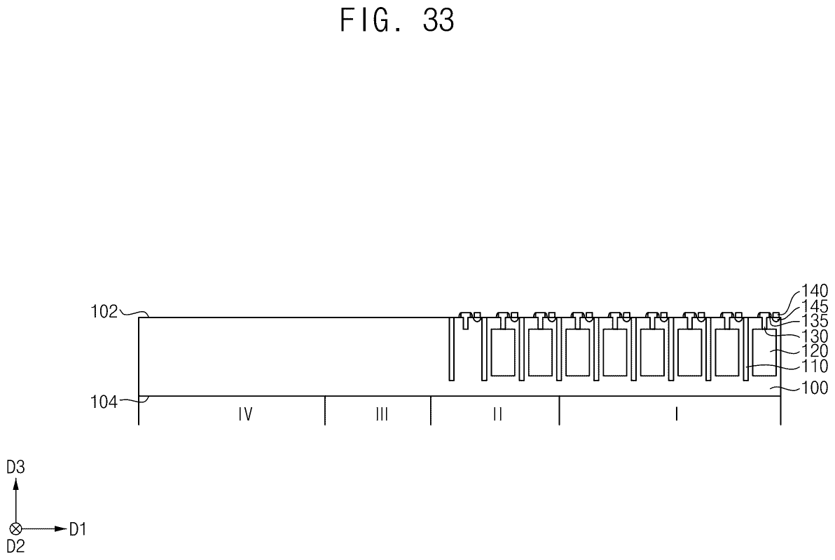

FIGS. 33 to 38 are cross-sectional views illustrating a method of manufacturing an image sensor in accordance with some example embodiments.

Referring to FIG. 33, a division structure 110 and a photodiode 120 may be formed in a first substrate 100 including first, second, third and fourth regions I, II, III and IV, according to the processes illustrated with reference to FIGS. 5 to 24, a transfer gate (TG) 130, a gate spacer 135, a pad structure 140 and a floating diffusion region (FD) 145 may be formed.

In example embodiments, p-type impurities may be doped into the first substrate 100 to form a p-type well.

The division structure 110 may be formed in a first trench extending in the third direction D3 through the first substrate 100 in the first and second regions I and II. In example embodiments, the division structure 110 may have a lattice shape arranged in the first and second directions D1 and D2 in a plan view.

The photodiode 120 may be formed by doping n-type impurities in the p-type well in the first substrate 100 in the first and second regions I and II, and thus the photodiode 120 and the p-type well may form a PN junction diode. In example embodiments, after forming the first trench for the division structure 110, p-type impurities may be highly doped into a portion of the first substrate 100 adjacent to the first trench.

In example embodiments, the photodiode 120 may be formed after forming the division structure 110. Alternatively, the photodiode 120 may be formed before forming the division structure 110.

The TG 130 may be formed in a second trench extending in the third direction D3 extending from the first surface 102 of the first substrate 100 downwardly. In example embodiments, the TG 130 may include a buried portion in the second trench, and a protrusion portion disposed on the buried portion and having an upper surface higher than the first surface 102 of the first substrate 100.

The gate spacer 135 may be formed to cover a sidewall of the TG 130.

The pad structure 140 may be formed on the first surface 102 of the first substrate 100 to include polysilicon doped with n-type impurities.

An annealing process may be performed on the pad structure 140 so that the n-type impurities may be diffused into an upper portion of the first substrate 100. Thus, the FD 145 may be formed at the upper portion of the first substrate 100 adjacent to the TG 130.

The TG 130, the photodiode 120 and the FD 145 may collectively form a transfer transistor.

Pixel transistors, e.g., a source follower transistor, a reset transistor and a select transistor may be formed on the first surface 102 of the first substrate 100.

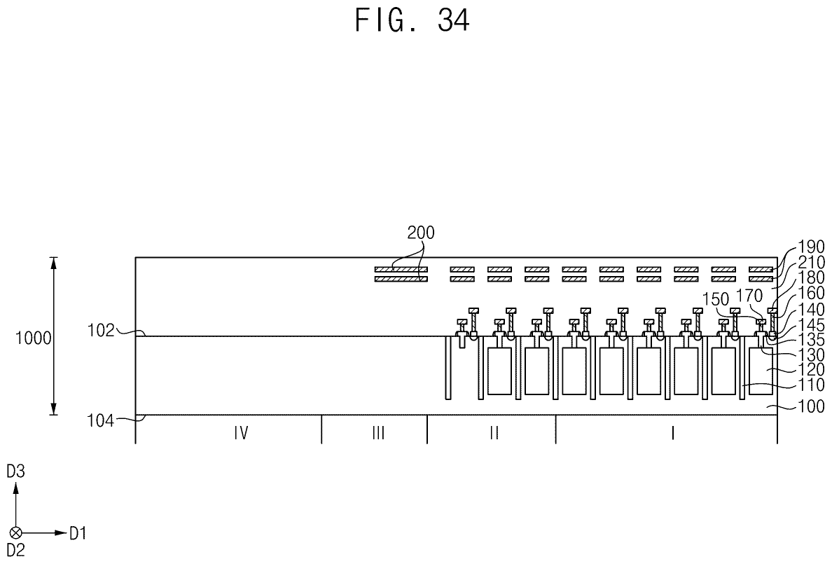

Referring to FIG. 34, first and second vias 150 and 160, first to fourth wirings 170, 180, 190 and 200, and a first insulating interlayer 210 may be formed on the first surface 102 of the first substrate 100.

The first via 150 may contact the TG 130, and may be connected to the first wiring 170. The second via 160 may contact the pad structure 140, and may be connected to the second wiring 180. The first to third wirings 170, 180 and 190 may be formed in the first and second regions I and II, and the fourth wiring 200 may be formed in the third region III.

Vias and wirings may be further formed on the first surface 102 of the first substrate 100 to be electrically connected to the pixel transistors, e.g., the source follower transistor, the reset transistor and the select transistor. In example embodiments, the first and second vias 150 and 160 and the first to fourth wirings 170, 180, 190 and 200 may be formed by a dual damascene process or a single damascene process.

The first substrate 100, the division structure 110, the photodiode 120, the transfer transistor, the pad structure 140, the pixel transistors, the first and second vias 150 and 160, the first to fourth wirings 170, 180, 190 and 200, and the first insulating interlayer 210 may collectively form a photoelectric conversion circuit structure 1000.

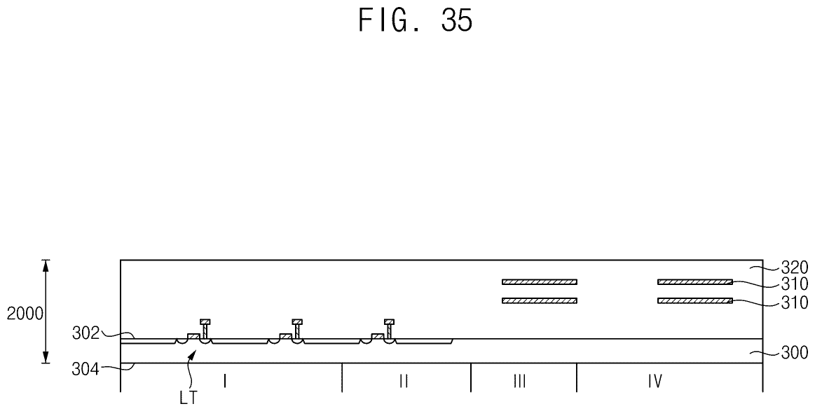

Referring to FIG. 35, logic transistors LT may be formed on a third surface 302 of a second substrate 300 including the third surface 302 and a fourth surface 304 opposite to the third surface 302 in the third direction D3.

A fifth wiring 310 and a second insulating interlayer 320 may be formed on the third surface 302 of the second substrate 300.

FIG. 35 shows that the fifth wiring 310 is formed at two levels, however, the disclosed concepts are not limited thereto, and a plurality of fifth wirings 310 may be connected to one another by vias. In example embodiments, the fifth wiring 310 may be formed by a dual damascene process or a single damascene process.

The second substrate 300, the second insulating interlayer 320, the logic transistors LT and the fifth wiring 310 may collectively form a logic circuit structure 2000.

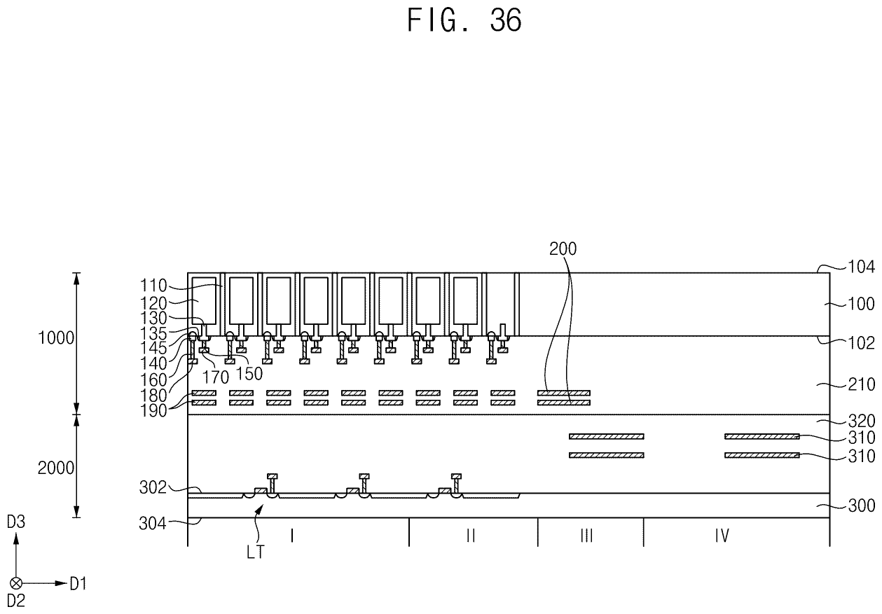

Referring to FIG. 36, the first insulating interlayer 210 on the first substrate 100 and the second insulating interlayer 320 on the second substrate 300 may be bonded to one another, and a portion of the first substrate 100 adjacent to the second surface 104 may be removed.

In example embodiments, the first and second insulating interlayers 210 and 320 may be bonded to one another through a bonding layer. Alternatively, the first and second insulating interlayers 210 and 320 may be directly bonded to one another without a bonding layer. After bonding the first and second insulating interlayers 210 and 320, the bonded structure may be flipped so that the second surface 104 of the first substrate 100 may face upwardly.

As the first and second substrates 100 and 300 are bonded to one another, the fifth wiring 310 may be disposed in the third and fourth regions III and IV.

In example embodiments, the portion of the first substrate 100 adjacent to the second surface 104 may be removed by a polishing process, e.g., a grinding process. Thus, the division structure 110 may be exposed, and the division structure 110 may extend through the first substrate 100.

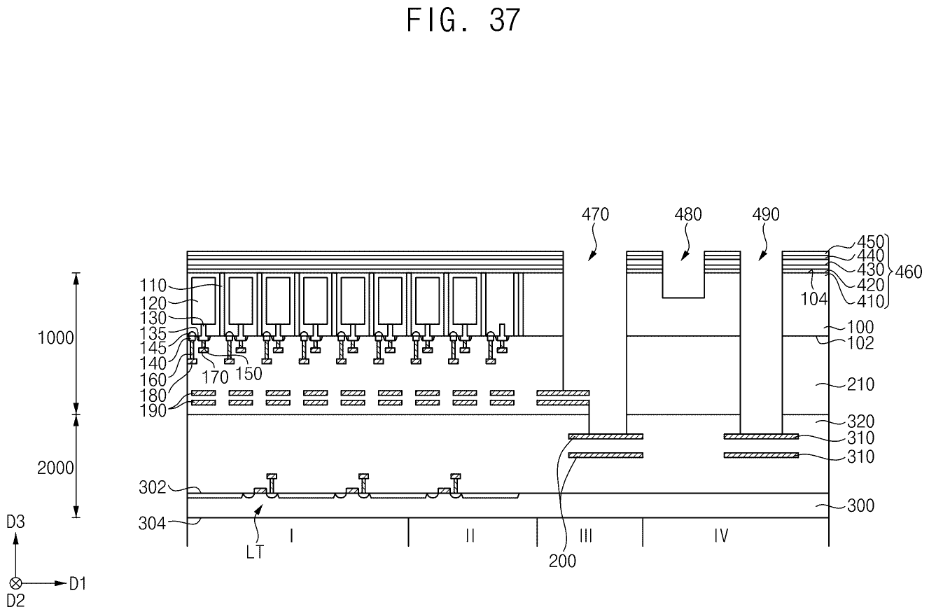

Referring to FIG. 37, a lower planarization layer 460 may be formed on the second surface 104 of the first substrate 100.

In example embodiments, the lower planarization layer 460 may include first to fifth layers 410, 420, 430, 440 and 450 sequentially stacked in the third direction D3.

The lower planarization layer 460, the first substrate 100, the first insulating interlayer 210 and an upper portion of the second insulating interlayer 320 may be removed in the third region III to form a first opening 470, the lower planarization layer 460 and an upper portion of the first substrate 100 in the fourth region IV may be removed to form a third trench 480, and the lower planarization layer 460, the first insulating interlayer 210 and the upper portion of the second insulating interlayer 320 in the fourth region IV may be removed to form a second opening 490.

The first opening 470 may expose the fourth wiring 200 in the first insulating interlayer 210 and the fifth wiring 310 in the second insulating interlayer 320, and the second opening 490 may expose the fifth wiring 310 in the second insulating interlayer 320.

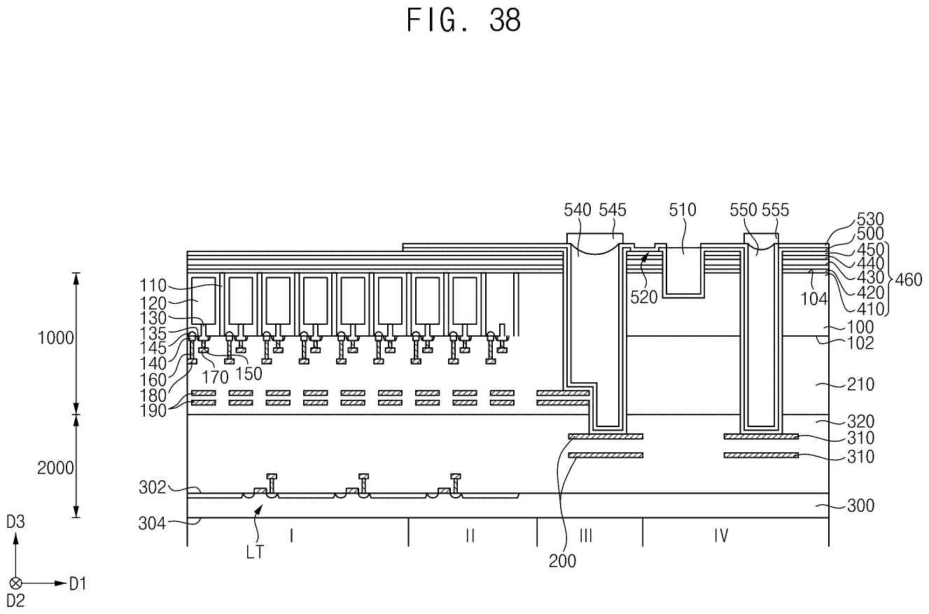

Referring to FIG. 38, a first conductive layer may be formed on bottoms and sidewalls of the first and second openings 470 and 490 and the third trench 480 and an upper surface of the lower planarization layer 460, a second conductive layer may be formed on the first conductive layer to fill the third trench 480, and an upper portion of the second conductive layer may be planarized until an upper surface of the first conductive layer is exposed, so that a pad 510 may be formed on the first conductive layer in the third trench 480 in the fourth region IV.

The planarization process may include a chemical mechanical polishing (CMP) process and/or an etch back process.

Before forming the first conductive layer, a barrier layer may be further formed on the bottoms and the sidewalls of the first and second openings 470 and 490 and the third trench 480 and the upper surface of the lower planarization layer 460.

The first conductive layer may be partially removed at a boundary between the third and fourth regions III and IV to form a fourth trench 520 exposing the upper surface of the lower planarization layer 460.

An insulation layer may be formed on upper surfaces of the first conductive layer and the pad 510 and a bottom and a sidewall of the fourth trench 520, a filling layer may be formed on the insulation layer to fill the first and second openings 470 and 490, and a planarization process may be performed on the filling layer until an upper surface of the insulation layer is exposed.

An etching process may be performed on the filling layer to remove a portion of the filling layer in the fourth trench 520, and thus a first filling pattern 540 may be formed on the insulation layer in the first opening 470 in the third region III, and a second filling pattern 550 may be formed on the insulation layer in the second opening 490 in the fourth region IV.

A capping layer may be formed on the first and second filling patterns 540 and 550 and the insulation layer, and may be patterned to form first and second capping patterns 545 and 555 on the first and second filling patterns 540 and 550, respectively.

A portion of the insulation layer in the first region I and a portion of the insulation layer on the pad 510 may be removed to form a first insulation pattern 530, and a portion of the first conductive layer in the first region I may be removed to form a conductive pattern 500. Thus, the upper surface of the lower planarization layer 460 may be exposed in the first region I.

If the barrier layer is formed under the first conductive layer, when the first conductive layer is partially removed, the barrier layer may also be partially removed to form a barrier pattern.

Portions of the conductive pattern 500 and the first insulation pattern 530 in the first opening 470 in the third region III, the first filling pattern 540 and the first capping pattern 545 may collectively form a first through via structure, and portions of the conductive pattern 500 and the first insulation pattern 530 in the second opening 490 in the fourth region IV, the second filling pattern 550 and the second capping pattern 555 may collectively form a second through via structure.

Referring to FIG. 31 again, a grid 600 and color filters 610 may be formed on the upper surface of the lower planarization layer 460 in the first region I.

Additionally, a light blocking layer 620 may be formed on the first insulation pattern 530 and the first capping pattern 545 in the second and third regions II and III.

An upper planarization layer 640 may be formed on the grid 600, the color filters 610, the light blocking layer 620, the first insulation pattern 530, the pad 510 and the second capping pattern 555 in the first to fourth regions I, II, III and IV, and a patterning process and a reflow process may be performed on the upper planarization layer 640 in the first region I to form an optical structure 630.

A transparent electrode layer 650 may be formed on the optical structure 630 and the upper planarization layer 640, and a portion of the transparent electrode layer 650 overlapping the pad 510 in the third direction D3 in the fourth region IV and a portion of the upper planarization layer 640 thereunder may be removed to form a third opening 660.

The lower planarization layer 460, the color filters 610, the grid 600, the first and second capping patterns 545 and 555, the light blocking layer 620, the optical structure 630, the upper planarization layer 640 and the transparent electrode layer 650 may collectively form a light transmitting structure 3000.

An upper wiring may be further formed to be electrically connected to the pad 510, so that the image sensor may be manufactured.

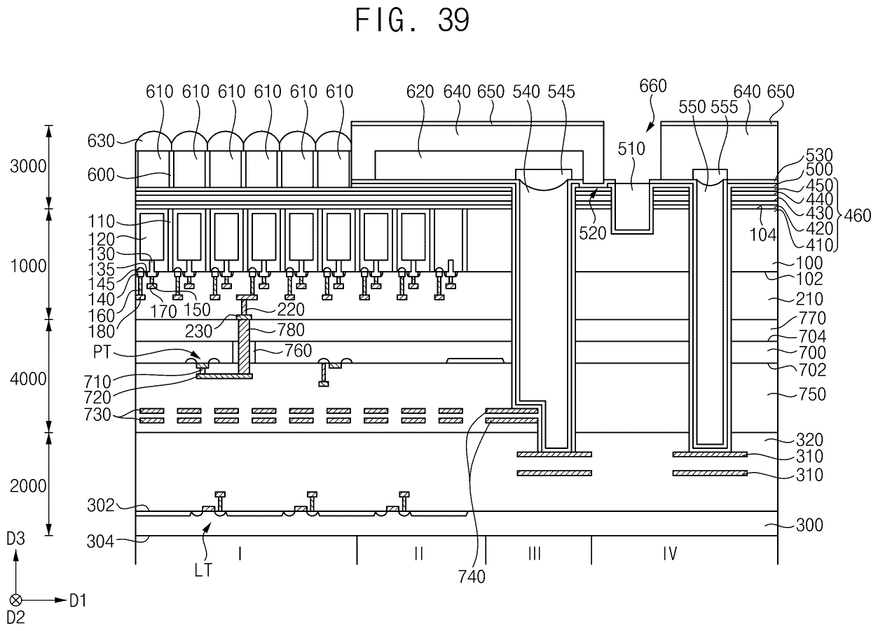

FIG. 39 is a cross-sectional view illustrating an image sensor in accordance with example embodiments.

This image sensor may be substantially the same as or similar to that of FIG. 21, except for the photoelectric conversion circuit structure and a pixel circuit structure.

Referring to FIG. 39, a pixel circuit structure 4000 may be disposed between the logic circuit structure 2000 and the photoelectric conversion circuit structure 1000.

The pixel circuit structure 4000 may include a third substrate 700, pixel transistors PT, a third via 710, sixth to eighth wirings 720, 730 and 740, a third insulating interlayer 750, a second insulation pattern 760, a fourth insulating interlayer 770 and a third through via 780.

The third substrate 700 may include a fifth surface 702 and a sixth surface 704 opposite to the fifth surface 702 in the third direction D3. FIG. 39 shows that the fifth surface 702 is disposed under the sixth surface 704.

The pixel transistors PT may be disposed on the fifth surface 702 of the third substrate 700. The pixel transistors PT may include, e.g., a source follower transistor, a reset transistor and a select transistor.

The third insulating interlayer 750 may be disposed under the fifth surface 702 of the third substrate 700.

Vias and wirings connected to the pixel transistors PT may be disposed in the third insulating interlayer 750. For example, the third via 710 may contact the pixel transistor PT and may be connected to the sixth wiring 720. FIG. 39 shows that each of the seventh and eighth wirings 730 and 740 are disposed at two levels, however, the disclosed concepts are not limited thereto.

The fourth insulating interlayer 770 may be disposed on the sixth surface 704 of the third substrate 700.

The third through via 780 may extend in the third direction D3 through the fourth insulating interlayer 770 and the third substrate 700 to contact an upper surface of the sixth wiring 720. However, the third through via 780 may be electrically insulated from the third substrate 700 by the second insulation pattern 760 extending through the third substrate 700.

The photoelectric conversion circuit structure 1000 may further include a fourth via 220 and a ninth wiring 230. The fourth via 220 may contact the second wiring 180 and may be connected to the ninth wiring 230. The ninth wiring 230 may be connected to the third through via 780.

The photoelectric conversion circuit structure 1000 may not include the pixel transistors PT and the third and fourth wirings 190 and 200.

The first through via structure may extend through the lower planarization layer 460, the first substrate 100, the first insulating interlayer 210, the fourth insulating interlayer 770, the third substrate 700, the third insulating interlayer 750 and an upper portion of the second insulating interlayer 320 in the third region III, and may contact the eighth wiring 740 in the third insulating interlayer 750 and the fifth wiring 310 in the second insulating interlayer 320.

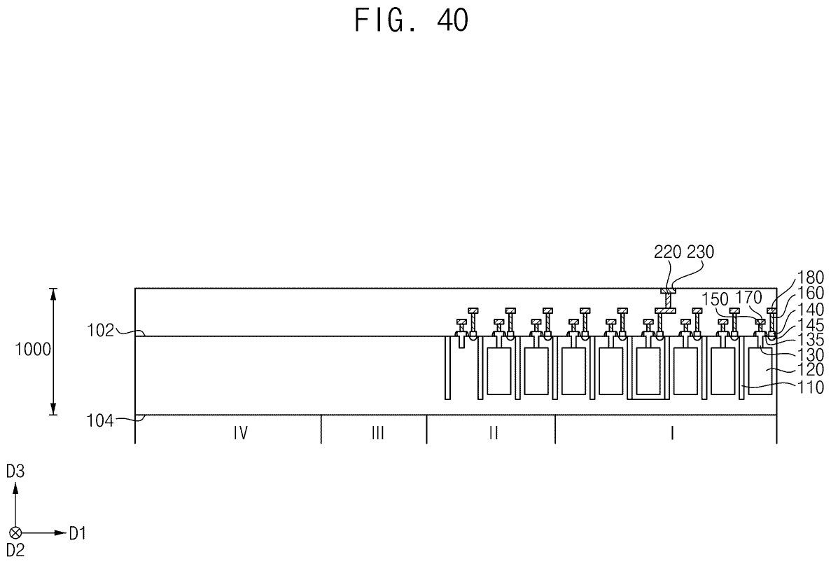

FIGS. 40 to 43 are cross-sectional views illustrating a method of manufacturing an image sensor in accordance with example embodiments. This method may include processes substantially the same as or similar to those illustrated with reference to FIGS. 33 to 38 and FIG. 32, and thus repeated explanations thereof are omitted herein.

Referring to FIG. 40, processes substantially the same as or similar to those illustrated with reference to FIGS. 33 and 34 may be performed.

However, the photoelectric conversion circuit structure 1000 may further include a fourth via 220 and a ninth wiring 230. The fourth via 220 may contact the second wiring 180 and may be connected to the ninth wiring 220.

The photoelectric conversion circuit structure 1000 may not include the pixel transistors PT and the third and fourth wirings 190 and 200.

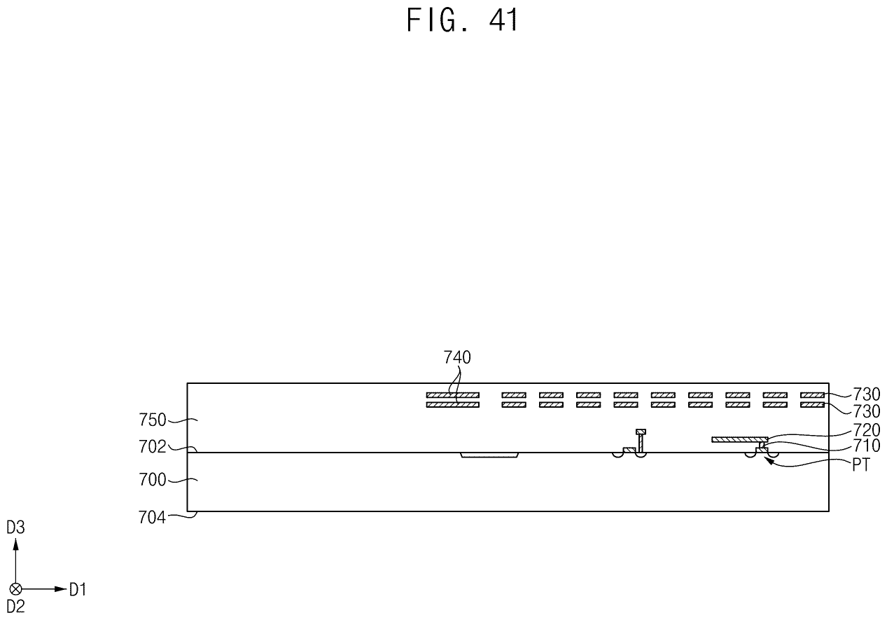

Referring to FIG. 41, pixel transistors PT may be formed on the fifth surface 702 of a third substrate 700 including the fifth surface 702 and a sixth surface 704 opposite to the fifth surface 702 in the third direction D3.

A third via 710, sixth to eighth wirings 720, 730 and 740, and a third insulating interlayer 750 may be formed on the fifth surface 702 of the third substrate 700.

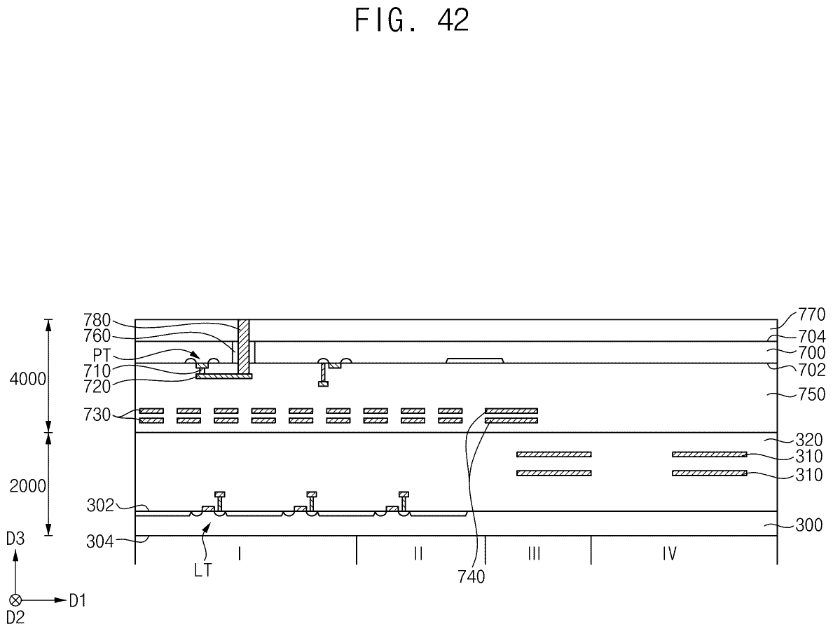

Referring to FIG. 42, the second insulating interlayer 320 on the second substrate 300 and the third insulating interlayer 750 on the third substrate 700 may be bonded to one another, and a portion of the third substrate 700 adjacent to the sixth surface 704 may be removed.

In example embodiments, the second and third insulating interlayers 320 and 750 may be bonded to one another through a bonding layer. Alternatively, the second and third insulating interlayers 320 and 750 may be directly bonded to one another without a bonding layer.

After bonding the second and third insulating interlayers 320 and 750, the bonded structure may be flipped so that the sixth surface 704 of the third substrate 700 may face upwardly.

As the second and third substrates 300 and 700 are bonded to one another, the eighth wiring 740 on the third substrate 700 may be disposed in the third and fourth regions III and IV.

In example embodiments, the portion of the third substrate 700 adjacent to the sixth surface 704 may be removed by a polishing process, e.g., a grinding process. A second insulation pattern 760 may be formed through a portion of the third substrate 700 overlapping the sixth wiring 720 in the third direction D3, and a fourth insulating interlayer 770 may be formed on the sixth surface 704 of the third substrate 700 and the second insulation pattern 760.

A third through via 780 may be formed through the seventh insulating interlayer 770, the second insulation pattern 760 and an upper portion of the third insulating interlayer 750 to contact an upper surface of the sixth wiring 720.

The third substrate 700, the pixel transistors PT, the third via 710, the sixth to eighth wirings 720, 730 and 740, the third insulating interlayer 750, the second insulation pattern 760, the fourth insulating interlayer 770 and the third through via 780 may collectively form a pixel circuit structure 4000.

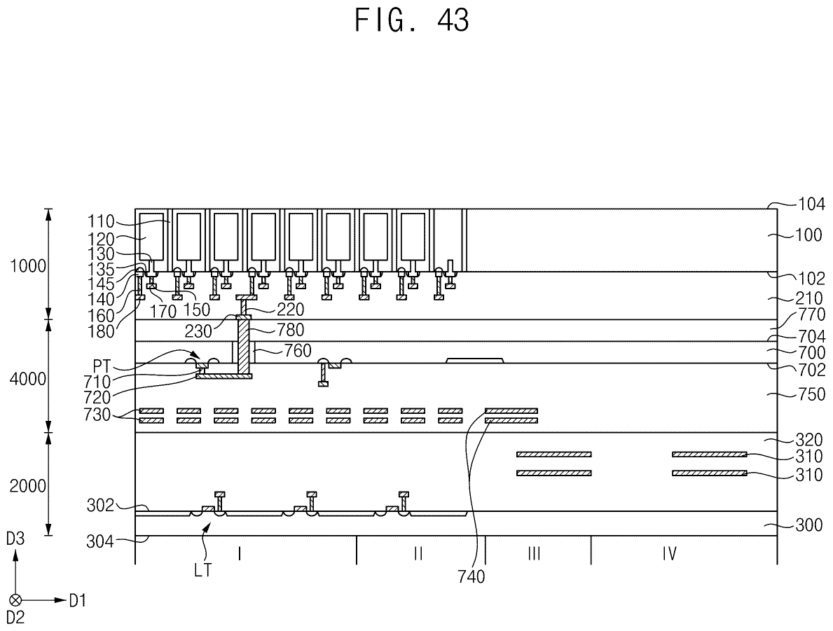

Referring to FIG. 43, the first insulating interlayer 210 on the first substrate 100 and the fourth insulating interlayer 770 on the third substrate 700 may be bonded to one another, and a portion of the first substrate 100 adjacent to the second surface 104 may be removed.

In example embodiments, the first and fourth insulating interlayers 210 and 770 may be bonded to one another through a bonding layer. Alternatively, the first and fourth insulating interlayers 210 and 770 may be directly bonded to one another without a bonding layer. After bonding the first and fourth insulating interlayers 210 and 770, the bonded structure may be flipped so that the second surface 104 of the first substrate 100 may face upwardly.

As the first and third substrates 100 and 700 are bonded to one another, the ninth wiring 230 on the first substrate 100 and the third through via 780 on the third substrate 700 may be connected to one another.

In example embodiments, the portion of the first substrate 100 adjacent to the second surface 104 may be removed by a polishing process, e.g., a grinding process. Thus, the division structure 110 may be exposed, and the division structure 110 may extend through the first substrate 100.

Referring to FIG. 39 again, processes substantially the same as or similar to those illustrated with reference to FIGS. 37 and 38 and FIG. 32 may be performed so that the image sensor may be manufactured.

As described above, although the present disclosure has been described with reference to example embodiments, those skilled in the art will readily appreciate that many modifications are possible in the example embodiments without materially departing from the novel teachings and advantages of the present disclosed concepts.

What is claimed is:

1. An image sensor comprising:
a unit pixel including:
a photodiode in a substrate, the photodiode being doped with n-type impurities;
a pair of vertical transfer gates on the photodiode, each of the pair of vertical transfer gates extending through a portion of the substrate; and
a floating diffusion region at an upper portion of the substrate between the pair of vertical transfer gates, the floating diffusion region including first impurities;
a pad pattern on the floating diffusion region, the pad pattern including polysilicon doped with the first impurities; and
a contact plug on an upper surface of the pad pattern.

2. The image sensor of claim 1, further comprising an etch stop layer on sidewalls and upper surfaces of the pair of vertical transfer gates and an upper surface of the substrate.

3. The image sensor of claim 2, wherein the pad pattern extends through the etch stop layer and contacts an upper surface of the floating diffusion region.

4. The image sensor of claim 2, wherein the etch stop layer includes silicon oxide.

5. The image sensor of claim 1, wherein a lower surface of the contact plug is higher than an upper surface of the substrate.

6. The image sensor of claim 1, wherein the first impurities are n-type impurities.

7. An image sensor comprising:
unit pixels arranged in a matrix having two rows and two columns, each of the unit pixels including:
a photodiode in a substrate, the photodiode being doped with n-type impurities;
a pair of vertical transfer gates on the photodiode, each of the pair of vertical transfer gates extending through a portion of the substrate; and
a floating diffusion region at an upper portion of the substrate between the pair of vertical transfer gates, the floating diffusion region including first impurities;
a pad structure on the floating diffusion regions of the unit pixels; and
a contact plug contacting an upper surface of the pad structure,
wherein:
the unit pixels form a pixel group,
the floating diffusion regions of the unit pixels are connected to one another at a center of the pixel group to form a common floating diffusion region, and
the common floating diffusion region including the first impurities.

8. The image sensor of claim 7, wherein the floating diffusion region of each of the unit pixels extends from the center of the pixel group toward a center of a corresponding one of the unit pixels.

9. The image sensor of claim 7, wherein the common floating diffusion region has substantially a shape of an “X” in a plan view.

10. The image sensor of claim 7, wherein the pad structure has substantially a shape of an “X” in a plan view.

11. The image sensor of claim 7, wherein the contact plug is disposed at the center of the pixel group.

12. The image sensor of claim 7, wherein:
the contact plug includes first, second, third and fourth contact plugs, and
each of the first to fourth contact plugs contacts an upper surface of a portion of the pad structure between the pair of vertical transfer gates of a corresponding one of the unit pixels.

13. The image sensor of claim 7, wherein a lower surface of the contact plug is higher than an upper surface of the substrate.

14. An image sensor comprising:
a substrate having a pixel group, the pixel group including unit pixels arranged in a matrix having two rows and two columns;
a pad structure on the substrate, the pad structure including a first central portion and first, second, third and fourth extension portions, the first central portion being disposed at a center of the pixel group of the substrate in a plan view, and the first, second, third and fourth extension portions extending from the first central portion toward centers of the unit pixels, respectively, of the substrate in a plan view, and the pad structure including polysilicon doped with first impurities; and
a common floating diffusion region at an upper portion of the substrate overlapping the pad structure in a vertical direction substantially perpendicular to an upper surface of the substrate, the common floating diffusion region including the first impurities,
wherein each of the unit pixels includes:
a photodiode in the substrate, the photodiode being doped with n-type impurities; and
a pair of vertical transfer gates on the photodiode, each of the pair of vertical transfer gates extending through a portion of the substrate.

15. The image sensor of claim 14, wherein the common floating diffusion region includes a second central portion and fifth, sixth, seventh and eighth extension portions, the second central portion being disposed at the center of the pixel group of the substrate in a plan view, and the fifth, sixth, seventh and eighth extension portions extending from the second central portion toward the centers of the unit pixels, respectively, of the substrate in a plan view, and
wherein the second central portion and the fifth to eighth extension portions of the common floating diffusion region overlap the first central portion and the first to fourth extension portions, respectively, of the pad structure substantially in the vertical direction.

16. The image sensor of claim 14, wherein the first central portion of the pad structure has substantially a shape of a rectangle in a plan view.

17. The image sensor of claim 14, wherein the first central portion of the pad structure has substantially a shape of a circle or an ellipse in a plan view.

18. The image sensor of claim 14, wherein the first impurities are n-type impurities.

19. The image sensor of claim 14, further comprising a contact plug contacting an upper surface of the first central portion of the pad structure.

20. The image sensor of claim 14, further comprising first, second, third and fourth contact plugs contacting upper surfaces of the first, second, third and fourth extension portions, respectively, of the pad structure.
